(19) United States
(12) Patent Application Publication
(10) Pub. No.: US 2003/0218246 A1
(43) Pub. Date: Nov. 27, 2003

(54) Semiconductor device passing large electric current

(76) Inventors: Hirofumi Abe, Gamagori-City (JP); Hiroyuki Ban, Hazu-gun (JP); Yoshinori Arashima, Gamagori-City (JP); Hirokazu Itakura, Hazu-gun (JP); Takao Kuroda, Nagoya-City (JP); Noriyuki Iwamori, Okazaki-City (JP); Satoshi Shiraki, Toyohashi-City (JP)

Correspondence Address: POSZ & BETHARDS, PLC, 11250 ROGER BACON DRIVE, SUITE 10, RESTON, VA, 20190, US

(21) Appl. No.: 10/440,159

(22) Filed: May 19, 2003

(30) Foreign Application Priority Data
May 22, 2002 (JP) 2002-147944
Jun. 13, 2002 (JP) 2002-172788
Jun. 13, 2002 (JP) 2002-172789
Jun. 13, 2002 (JP) 2002-172790
Jun. 13, 2002 (JP) 2002-172791
Jun. 27, 2002 (JP) 2002-187770

(51) Int. Cl. H01L 23/48

(52) U.S. Cl. 257/734

(57) ABSTRACT

In a semiconductor device, a plurality of bump electrodes are formed for a source pad or a drain pad. The bump electrodes and the source or drain pad are connected with each other through wiring patterns. Thus, the following effect is produced unlike cases where one bump electrode is connected with one source pad or one drain pad through a wiring pattern: An amount of current that passes through each of the bump electrodes can be reduced, so that a breakdown of the bump electrodes is lessened.

### CROSS REFERENCE TO RELATED APPLICATIONS

This application is based on and incorporates herein by reference Japanese Patent Applications No. 2002-147944 filed on May 22, 2002, No. 2002-172788 filed on Jun. 13, 2002, No. 2002-172789 filed on Jun. 13, 2002, No. 2002-172790 filed on Jun. 13, 2002, No. 2002-172791 filed on Jun. 13, 2002, and No. 2002-187770 filed on Jun. 27, 2002.

### FIELD OF THE INVENTION

The present invention relates to a semiconductor device having wiring and bump electrodes to be connected with connection pads on a semiconductor substrate. In particular, the semiconductor device is enabled to pass relatively large electric current.

### BACKGROUND OF THE INVENTION

A semiconductor device of CSP (Chip Size Package) structure where the chip size is substantially equal to the package size is known as one of this type of semiconductor devices. FIGS. 5 and 6 illustrate cases where the CSP structure is applied to a semiconductor device where relatively large (electric) current is passed, for example, a power device.

As illustrated in FIGS. 5 and 6, a semiconductor device 20 has a source pad 2a and a drain pad 2b (connection pads) on the side of the surface of a semiconductor substrate 1. Each of these pads is formed of an aluminum electrode or the like and has (electric) potential (e.g. source potential or drain potential). On the source pad 2a and the drain pad 2b, a passivation film 3 composed of silicon oxide, silicon nitride, or the like is formed so that the central parts of the source pad 2a and the drain pad 2b are exposed.

Furthermore, to constitute the CSP structure, an insulating film 4 composed of polyimide resin is formed on the passivation film 3 so that the central parts of the source pad 2a and the drain pad 2b are exposed.

Furthermore, wiring patterns 5 for electrically connecting the source pad 2a and drain pad 2b with electrodes 6, described below, respectively are formed on the insulating film 4. An electrode 6 is formed on each of the wiring patterns 5 in a specified position. Furthermore, a sealing film 7 composed of epoxy resin or the like is formed on the entire surface of the semiconductor substrate 1 so that the electrodes 6 are covered therewith.

Furthermore, the upper end face of the sealing film 7 is shaved and polished to expose the end faces of the electrodes 6 and bump electrodes 6a as external connection terminals are formed on the exposed electrodes 6.

Here, consideration will be given to a case where a power element (indicated as region 8), such as a power transistor, is formed in the surface of the semiconductor substrate 1. This power element 8 is electrically connected with the bump electrodes 6a through the source pad 2a, drain pad 2b, wiring patterns 5, and electrodes 6, and is to be connected with the outside. Many power elements 8 are driven at large current of not less than 100 mA, and thus it is required to pass large current through the source pad 2a and drain pad 2b which are connected with the power element 8.

As illustrated in FIG. 6, however, structure where a bump electrode 6a is connected with one source pad 2a or one drain pad 2b, through a wiring pattern 5 poses a problem. When large current is passed through the bump electrodes 6a connected with the power element 8 to drive the power element 8, the current passed through the bump electrodes 6 exceeds an allowable amount of current. As a result, the bump electrodes 6a are broken down by overcurrent.

### SUMMARY OF THE INVENTION

It is an object of the present invention to lessen a breakdown of bump electrodes and pass large current through the bump electrodes in a semiconductor device having wiring and the bump electrodes connected with connection pads on a semiconductor substrate.

To achieve the above object, a semiconductor device is provided with the following. A semiconductor device includes a connection pad on a substrate, a plurality of bump electrodes formed for the connection pad, and wiring for connecting the connection pad with the bump electrodes. This structure reduces an amount of current per a bump electrode, so that a breakdown of the bump electrode is lessened.

It is preferable that a semiconductor device is provided with areal wiring which encircles the bump electrodes and the connection pad to connect the connection pad with the plurality of the bump electrodes. In one embodiment, the areal wiring is comb-shaped with a protrusion and reception portions. In another embodiment, the areal wiring is provided with a slit. These structures enable the semiconductor device to be inhibited from having problem generated by large current, for instance, in a case where a CSP structure is used for such a power element.

### BRIEF DESCRIPTION OF THE DRAWINGS

The above and other objects, features and advantages of the present invention will become more apparent from the following detailed description made with reference to the accompanying drawings. In the drawings:

FIG. 1 is a schematic drawing illustrating cross-sectional structure of a semiconductor device in a first embodiment of the present invention;

FIG. 2 is a schematic plan view of the semiconductor device in the first embodiment;

FIGS. 3A to 3E are schematic drawings illustrating a manufacturing method for the semiconductor device in the first embodiment;

FIG. 4 is a schematic drawing illustrating an example where wiring patterns are formed in areal wiring;

FIG. 5 is a schematic drawing illustrating cross-sectional structure of a semiconductor device of a related art;

FIG. 6 is a schematic plan view of the semiconductor device of the related art;

FIG. 7 is a schematic drawing illustrating planar structure of a semiconductor device in a second embodiment of the present invention;

FIG. 8 is a schematic drawing illustrating cross-sectional structure of the semiconductor device in the second embodiment;

FIG. 9 is another schematic drawing illustrating cross-sectional structure of the semiconductor device in the second embodiment;

FIG. 10 is a schematic plan view of the semiconductor device in the second embodiment;

FIG. 11 is a schematic drawing illustrating a modification to the second embodiment;

FIG. 12 is a schematic drawing illustrating cross-sectional structure of a semiconductor device in a third embodiment of the present invention;

FIG. 13 is a schematic plan view of the semiconductor device in the third embodiment;

FIGS. 14A to 14E are schematic drawings illustrating a manufacturing method for the semiconductor device in the third embodiment;

FIGS. 15A and 15B are schematic drawings illustrating modifications to the third embodiment;

FIG. 16 is a schematic drawing illustrating the cross-sectional structure of a semiconductor device of a related art;

FIG. 17 is a schematic plan view of the semiconductor device of the related art;

FIG. 18 is a schematic drawing illustrating planar structure of a semiconductor device in a fourth embodiment of the present invention;

FIG. 19 is a schematic sectional view taken along line XIX-XIX of FIG. 18;

FIG. 20 is a schematic drawing illustrating the semiconductor device illustrated in FIG. 19, as is mounted on a mounting board;

FIGS. 21A to 21E are schematic drawings illustrating a manufacturing method for the semiconductor device in the fourth embodiment;

FIG. 22 is a schematic drawing illustrating a modification to the fourth embodiment;

FIG. 23 is a schematic drawing illustrating planar structure of a semiconductor device of a related art;

FIG. 24 is a schematic sectional view taken along line XXIV-XXIV of FIG. 23;

FIG. 25 is a schematic drawing illustrating the semiconductor device illustrated in FIG. 24, as is mounted on a mounting board;

FIG. 26 is a schematic drawing illustrating cross-sectional structure of a semiconductor device in a fifth embodiment of the present invention;

FIG. 27 is a schematic plan view of the semiconductor device in the fifth embodiment;

FIGS. 28A to 28E are schematic drawings illustrating a manufacturing method for the semiconductor device in the fifth embodiment;

FIGS. 29A and 29B are schematic drawings illustrating modifications to the fifth embodiment;

FIG. 30 is a schematic drawing illustrating cross-sectional structure of a semiconductor device of a related art;

FIG. 31 is a schematic plan view of the semiconductor device of the related art;

FIG. 32 is a schematic plan view of a multiple-unit IC package in a sixth embodiment of the present invention;

FIG. 33 is an enlarged plan view of a power element portion in FIG. 32;

FIG. 34 is a partial schematic sectional view of the power element portion taken in a direction of chip thickness;

FIG. 35 is a schematic plan view of a first modification to the multiple-unit IC package in the sixth embodiment;

FIG. 36 is an enlarged plan view of the power element portion in FIG. 35;

FIG. 37 is a schematic plan view of a second modification to the multiple-unit IC package in the sixth embodiment;

FIG. 38 is a schematic plan view of a third modification to the sixth embodiment;

FIG. 39 is a schematic sectional view of a fourth modification to the sixth embodiment;

FIG. 40 is a schematic plan view illustrating an example of the layout pattern for elements in chip in a multiple-unit IC package of a related art; and

FIG. 41 is a schematic plan view illustrating a plurality of bumps formed on the chip illustrated in FIG. 40 with a specified pitch.

### DETAILED DESCRIPTION OF THE PREFERRED EMBODIMENTS

### First Embodiment

Referring to the drawings, a first embodiment where a semiconductor device of the present invention is applied to a semiconductor device of CSP (Chip Size Package) structure will be described below. In this embodiment, the CSP structure is applied to a semiconductor device, for example, a power device where relatively large current is passed.

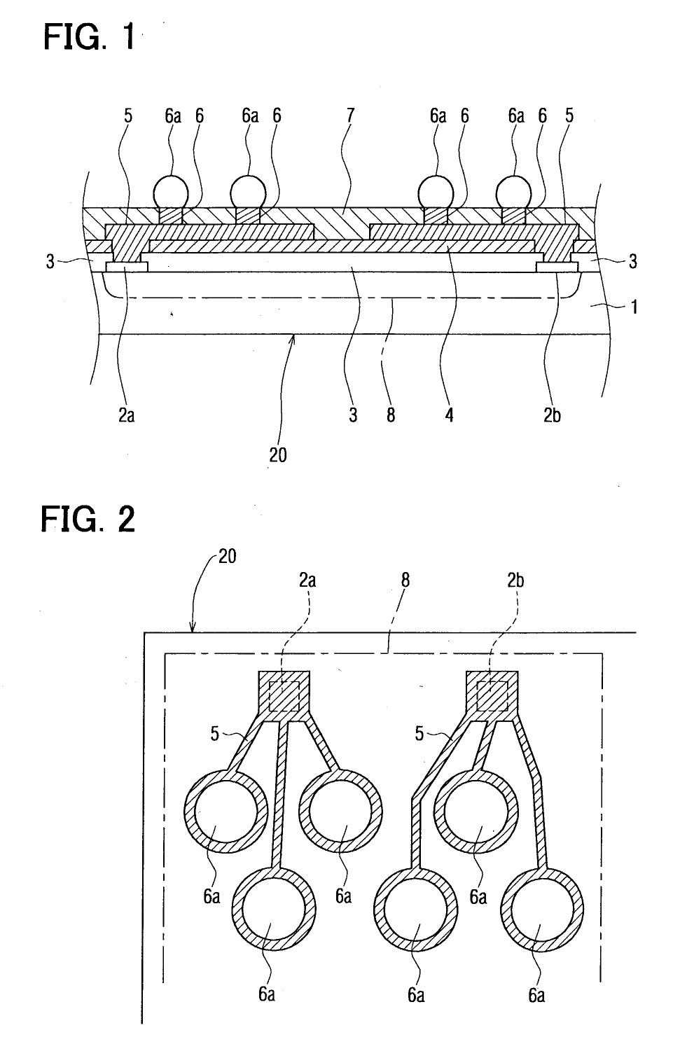

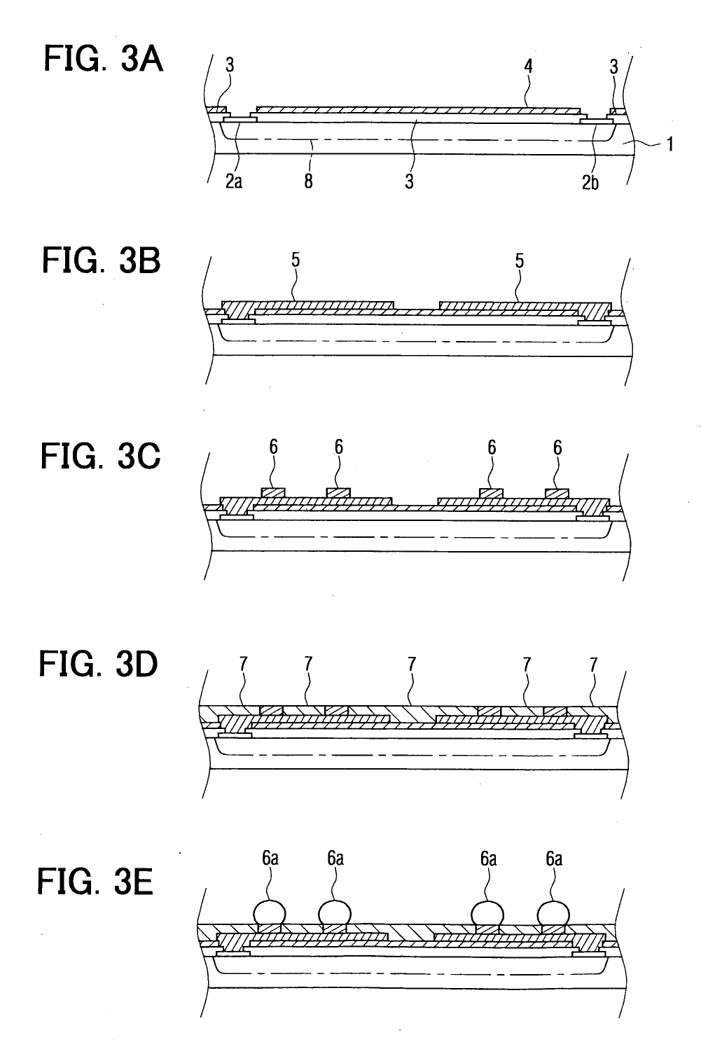

FIG. 1 illustrates schematic cross-sectional structure of a semiconductor device 20 in the first embodiment of the present invention. FIG. 2 illustrates a schematic plan view of the semiconductor device 20, and FIGS. 3A to 3E illustrate a manufacturing method for the semiconductor device 20. In FIG. 2, a resin film 7 is omitted.

First, the semiconductor device 20 in this embodiment has a power element (indicated as region 8), such as a power transistor, formed in a semiconductor substrate 1, as illustrated in FIGS. 1 and 2. A source pad 2a and a drain pad 2b are, as connection pads, formed on the source portion and the drain portion of the power element 8, respectively. The source pad 2a and the drain pad 2b are formed of aluminum electrodes or the like and have source (electric) potential and drain (electric) potential, respectively.

As shown in FIG. 2, on the source portion, a plurality of bump electrodes 6a are formed for one source pad 2a that has the source potential, and the bump electrodes 6a and the source pad 2a are connected with each other through wiring patterns 5. On the drain portion, similarly, a plurality of bump electrodes 6a are formed for one drain pad 2b that has the drain potential, and the bump electrodes 6a and the drain pad 2b are connected with each other through wiring patterns 5.

The semiconductor device 20 in this embodiment has the source pad 2a and drain pad 2b on the side of the surface of the semiconductor substrate 1. On the source pad 2a and the drain pad 2b, a passivation film 3 composed of silicon oxide, silicon nitride, or the like is formed so that the central parts of the source pad 2a and the drain pad 2b are exposed.

To constitute the CSP structure, an insulating film 4 composed of polyimide resin or the like is formed on the passivation film 3 so that the central parts of the source pad 2a and the drain pad 2b are exposed. Furthermore, the insulating film 4 is formed so that the insulating film 4 is positioned below the electrodes 6, described below.

On the insulating film 4, wiring patterns 5 are, as wiring, formed with electrically connecting the source pad 2a and drain pad 2b with the electrodes 6 described below, respectively. The electrodes 6 are formed on the wiring patterns 5 in specified positions. A sealing film 7 composed of epoxy resin or the like is formed on the entire surface of the semiconductor substrate 1 so that the electrodes 6 are covered therewith.

The upper end face of the sealing film 7 is shaved and polished to expose the electrodes 6, and bump electrodes 6a as external connection terminals are formed on the exposed electrodes 6.

A power element 8 is formed in the surface of the semiconductor substrate 1. This power element 8 is electrically connected with the bump electrodes 6a through the source pad 2a, drain pad 2b, wiring patterns 5, and electrodes 6, and is to be connected with the outside.

Here, referring to FIGS. 3A to 3E, a manufacturing process for the semiconductor device 20 in this embodiment will be described.

First, as illustrated in FIG. 3A, the power element 8, such as a power transistor, is formed in the surface of the semiconductor substrate 1. Next, the source pad 2a and drain pad 2b comprising aluminum electrodes or the like are formed on the surface of the semiconductor substrate 1. On the source pad 2a and the drain pad 2b, the insulating film composed of silicon oxide, silicon nitride, or the like is formed as a passivation film 3 so that the central parts of the source pad 2a and the drain pad 2b are exposed. Subsequently, the insulating film 4 composed of polyimide resin or the like is formed on the passivation film 3 so that the central parts of the source pad 2a and the drain pad 2b are exposed. Furthermore, the insulating film is formed so that the insulating film is positioned below the electrodes 6 described below. This insulating film 4 is formed, for example, by applying polyimide resin to the entire surface of the semiconductor substrate 1, curing the resin, and then subjecting the workpiece to insulation patterning using a specified resist pattern.

Subsequently, after the resist is stripped off, the wiring patterns 5 composed of copper, aluminum, or the like are respectively formed on the source pad 2a and the drain pad 2b, exposed in openings formed in the insulating film 4, as illustrated in FIG. 3B. Each of the wiring patterns 5 is formed by applying and curing photoresist for a conductor layer, performing patterning to form openings in specified shape using photolithography, and subjecting the areas opened by this resist to electrolytic plating.

Subsequently, as illustrated in FIG. 3C, the electrodes 6 composed of copper, solder, or the like having favorable conductive properties are formed on the wiring patterns 5 in specified positions. The electrodes 6 are formed by applying curing photoresist for electrode formation, forming openings to expose the specified points in the wiring patterns 5, and subjecting the interior of the openings to electrolytic plating.

Subsequently, as illustrated in FIG. 3D, for example, epoxy resin is applied to the entire surface of the semiconductor substrate 1 and cured to form the sealing film 7 so that the electrodes 6 are covered therewith.

Subsequently, as illustrated in FIG. 3E, the upper end face of the sealing film 7 is shaved and polished to expose the end faces of the electrodes 6, and bump electrodes 6a composed of solder or the like are formed in these exposed regions. Thus, the semiconductor device 20 as illustrated in FIG. 1 is finished.

Many power elements 8 are usually driven at large current of not less than 100 mA, as mentioned above. Therefore, if a power element 8, such as a power transistor, is formed in the surface of the semiconductor substrate 1, the large current need to be passed through the source pad 2a and the drain pad 2b connected with the power element 8.

However, structure where one bump electrode 6a is connected with one source pad 2a or with one drain pad 2b, respectively, through wiring patterns 5 poses a problem. When large current is passed through the bump electrode 6a connected with a power element 8 to drive the power element 8, the current passed through the bump electrodes 6a exceeds an allowable amount of current. As a result, the bump electrodes 6a are broken down by overcurrent.

To cope with this, in this embodiment, a plurality of the bump electrodes 6a are connected with the source pad 2a or with the drain pad 2b, respectively, through the wiring pattern 5, as illustrated in FIG. 2. In this embodiment, three bump electrodes 6a are connected with one source pad 2a or with one drain pad 2b, respectively, through wiring patterns 5.

Therefore, in this embodiment, the following advantages are produced unlike cases where one bump electrode 6a is connected with one source pad 2a or with one drain pad 2b, respectively, through the wiring pattern 5: on the source or drain portion, an amount of current passed through one bump electrodes 6a can be reduced.

As a result, a breakdown of the bump electrodes 6a due to overcurrent is lessened even if large current is passed through the bump electrodes 6a to drive the power element 8.

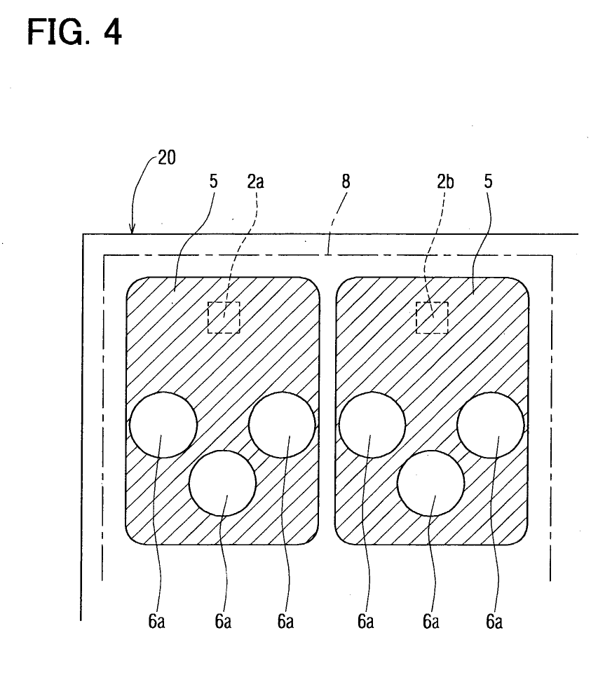

Furthermore, it is preferable that the wiring patterns 5 for connecting the source pad 2a and drain pad 2b with the respective bump electrodes 6a should be so designed that the bump electrodes 6a, the source pad 2a, and drain pad 2b are encircled therewith, as shown in FIG. 4. (These patterns are generally referred to as “areal wiring” or “extended wiring.”) In this case, some measures need to be taken to efficiently pass current: the bump electrodes 6a, the source pad 2a, and drain pad 2b need to be placed so that any other bump electrode 6a is not positioned between the bump electrodes 6a and the source pad 2a or between the bump electrodes 6a and the drain pad 2b.

Thus, variation in wiring resistance among the wiring patterns 5 can be lessened unlike cases where a plurality of bump electrodes 6a are connected with one source pad 2a or with one drain pad 2b through respective wiring patterns 5, as illustrated in FIG. 2. As a result, the concentration of current on a specific bump electrode 6a is lessened, and thus a breakdown of the bump electrodes 6a due to the concentration of the current is lessened. In addition, heat produced by the semiconductor device 20 can be cooled through the areal wiring 5, and thus the heat cooling capability of the semiconductor device 20 is enhanced.

In this case, the corners of the areal wiring of the wiring patterns 5 are preferably chamfered or rounded. Thus, concentration of current on the corners of the wiring patterns 5 is suppressed, and thus. deterioration in the wiring patterns 5 due to the concentration of the current is suppressed.

The present invention is not limited to the abovementioned embodiment and is applicable to a variety of modes.

The above embodiment is described taking as an example a case where three bump electrodes 6a are formed for one source pad 2a or for one drain pad 2b, respectively, as illustrated in FIG. 2 and FIG. 4. However, the numbers of the bump electrodes 6a, source pad 2a, and drain pad 2b are not limited to those in the above embodiment. It is essential only that the number of corresponding bump electrodes 6a be larger than the numbers of source pads 2a or drain pads 2b. Thus, current passed through one bump electrode 6a is reduced, and a breakdown of bump electrodes due to overcurrent is lessened.

Furthermore, in the above embodiment, the insulating film 4 is formed on the passivation film 3 so that the central parts of the source pad 2a and the drain pad 2b are exposed. This insulating film 4 is not necessarily required and the passivation film 3 may be substituted for the insulating film 4. In this case, the wiring patterns 5 and the sealing film 7 are formed on the passivation film 3.

### Second Embodiment

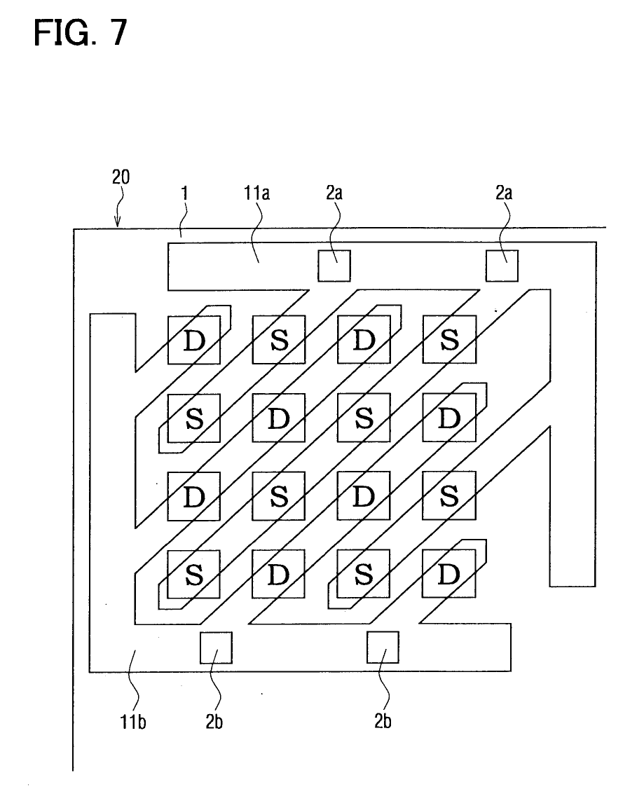

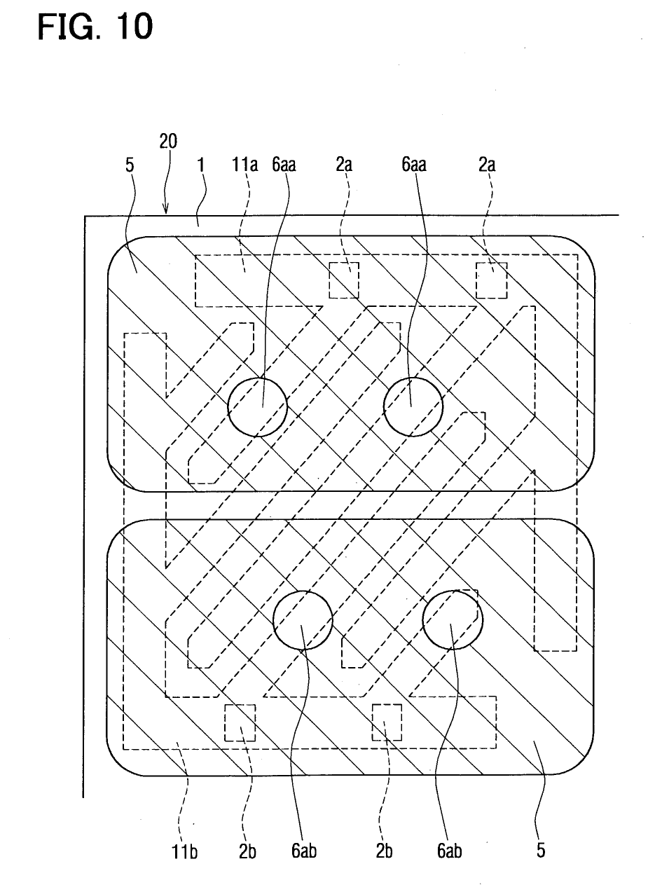

In the first embodiment, a plurality of bump electrodes are formed for one source pad or one drain pad. In contrast, in a second embodiment, a plurality of bump electrodes 6aa are formed for a plurality of source pads 2a or a plurality of drain pad 2b, as illustrated in FIG. 10. Here, the source and drain pads 2a, 2b are included in a source and drain leading layer 11a, 11b, respectively, as illustrated in FIG. 7 and 10. These will be explained later.

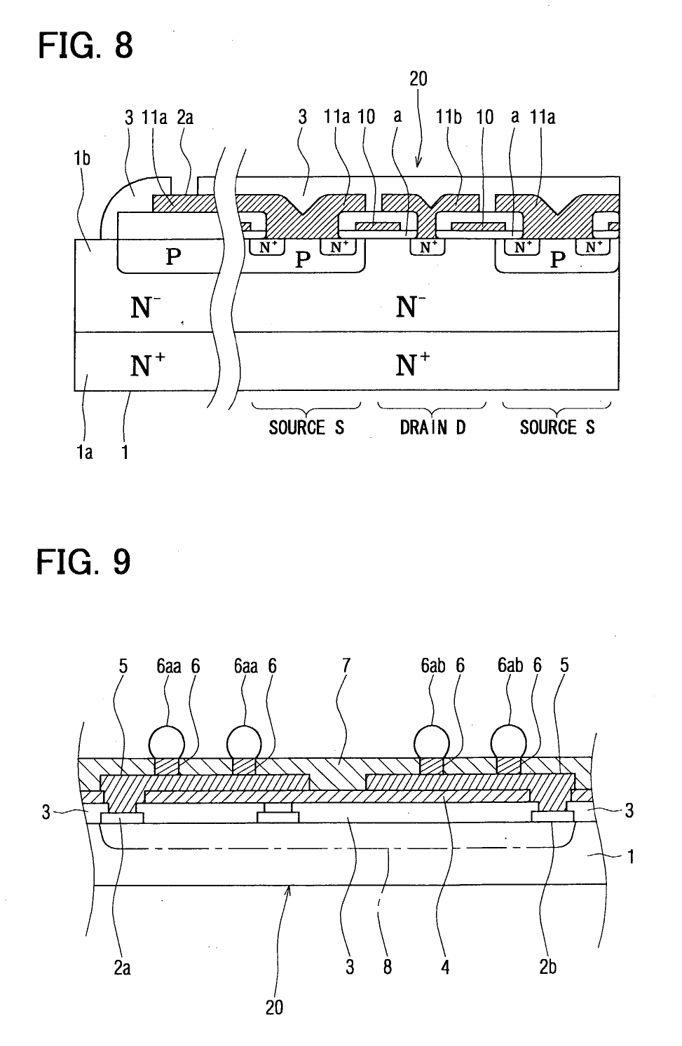

FIG. 7 illustrates the planar structure of a semiconductor device 20 in the second embodiment, and FIG. 8 illustrates the cross-sectional structure of the semiconductor device 20 in the second embodiment. FIG. 9 illustrates another aspect of the cross-sectional structure of the semiconductor device 20 in FIG. 8, and FIG. 10 shows a schematic plan view of the semiconductor device 20. In FIG. 9, gate electrodes 10 and the like interposed between the passivation film 3 and the semiconductor substrate 1, described below, are omitted, and in FIG. 10, a resin film 7 is omitted.

In the semiconductor device 20 in this embodiment, source cells S and drain cells D are formed on the surface of a semiconductor substrate 1 in a checkered pattern, as illustrated in FIG. 7. On the source cells S and the drain cells D, the source leading layer 11a and the drain leading layer 11b comprising aluminum electrodes or the like are formed. To connect together the source cells S and the drain cells D, respectively, without short-circuiting between them, the source leading layer 11a and the drain leading layer 11b are formed in comb shape.

On the source cells S and the drain cells D, an insulating film is formed, and on the insulating film, source contacts (not shown) and drain contacts (not shown) are formed, respectively.

The source leading layer 11a and the drain leading layer 11b formed in comb shape are formed with the source contacts and the drain contacts between the cells and the leading layers. On the source leading layer 11a and the drain leading layer 11b, a plurality of source pads 2a and a plurality of drain pads 2b are respectively formed. The source pads 2a and drain pads 2b thereby handle the same potential (i.e., source potential or drain potential).

Therefore, the source cells S and the drain cells D are respectively connected with the source leading layer 11a and the drain leading layer 11b through the source contacts and the drain contacts, and then with the source pads 2a and the drain pads 2b.

Furthermore, as illustrated in FIG. 8, the semiconductor device 20 in this embodiment uses a semiconductor substrate 1 obtained by forming a N⁻-epitaxial layer 1b on the surface of a N⁺-silicon substrate 1a. On the surface of the semiconductor substrate 1, a plurality of the source cells S and the drain cells D are formed in a checkered pattern, as mentioned above.

Furthermore, on the surface of the semiconductor substrate 1, gate electrodes 10 composed of doped silicon or the like are formed with a gate insulating film comprising a silicon oxide film or the like. The gate electrodes 10 are arranged in lattice shape so that the source cells S and the drain cells D are respectively encircled therewith.

The above-mentioned source leading layer 11a and the drain leading layer 11b are placed, insulated from the gate electrodes 10 openings are formed in specified regions in the passivation film 3 composed of silicon oxide, silicon nitride, or the like so that the source leading layer 11a and the drain leading layer 11b are locally exposed. The source pads 2a and the drain pads 2b are thereby formed.

As illustrated in FIG. 9 and FIG. 10, to constitute the CSP structure, an insulating film 4 composed of polyimide resin or the like is formed on the passivation film 3. The insulating film 4 is formed so that the central parts of the source pads 2a and the drain pads 2b are exposed and the insulating film 4 is positioned below the electrodes 6 described below.

On the insulating film 4, wiring patterns 5 for electrically connecting the above-mentioned source pads 2a and drain pad 2b with the electrodes 6, described below, respectively, are formed. A plurality of the electrodes 6 are formed on each of the wiring patterns 5 in specified positions. Furthermore, on the entire surface of the semiconductor substrate 1, a sealing film 7 composed of epoxy resin, acrylic resin, polyimide resin, or the like is formed so that the electrodes 6 are covered therewith.

The upper end face of the sealing film 7 is shaved and polished to expose the end faces of the electrodes 6. On the exposed electrodes 6, source bump electrodes 6a a and drain bump electrodes 6ab are formed as external connection terminals.

In FIG. 9, the region 8 refers to the above-mentioned power element formed in the semiconductor substrate 1.

The manufacturing process for the semiconductor device 20 in this embodiment is the same as that for the first embodiment illustrated in FIGS. 3A to 3E.

Also in this embodiment, similarly with the first embodiment, to lessen a breakdown of the source bump electrode 6aa or drain bump electrode 6ab, the wiring patterns 5 for connecting the source pads 2a with the source bump electrodes 6aa and the drain pads 2b with the drain bump electrodes 6ab are designed as areal wiring as illustrated in FIG. 10. More specifically, these patterns are so designed as to encircle the source bump electrodes 6aa and source pads 2a, and the drain bump electrodes 6ab and drain pads 2b in an overhead view relative to the surface of the semiconductor substrate 1.

Furthermore, similarly with the first embodiment, the concentration of current or stress on the corners of the wiring patterns 5 is suppressed by chamfering (rounding) the corners of the wiring patterns 5, as illustrated in FIG. 10. Thus, deterioration in the wiring patterns 5 due to the concentration of current and cracking due to the concentration of wiring are suppressed.

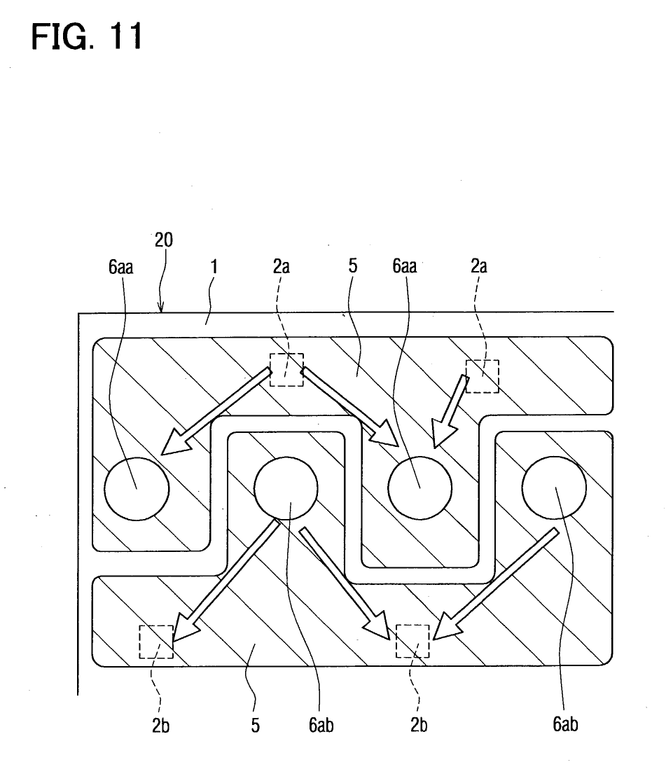

Furthermore, as illustrated in FIG. 11, there is a case where the source bump electrode 6aa and drain bump electrode 6ab are alternately disposed in a line. Here, an upper wiring pattern 5 so designed that the source bump electrodes 6aa and source pads 2a are encircled therewith are formed as areal wiring of comb shape having protrusion portions and reception portions. A lower wiring pattern 5 so designed that the drain bump electrodes 6ab and drain pads 2b are encircled therewith are also formed as areal wiring of comb shape having protrusion portions and reception portions.

With this shape, on the source portion, current flowing from the source pads 2a to the source bump electrodes 6aa can be dispersed, and on the drain portion, current flowing from the drain bump electrodes 6ab to the drain pads 2b can be dispersed.

As a result, variation in the amount of current passed through the source pads 2a and the drain pads 2b is suppressed, and thus the concentration of current on a specific source pad 2a or drain pad 2b is suppressed. In this case, the same effect as mentioned above can be produced by chamfering the corners of the wiring patterns 5.

The present invention is not limited to the abovementioned embodiment and is applicable to a variety of modes.

The numbers of the source bump electrodes 6aa, drain bump electrodes 6ab, source pads 2a, and drain pad 2b are not limited to those in the above embodiment.

### Third Embodiment

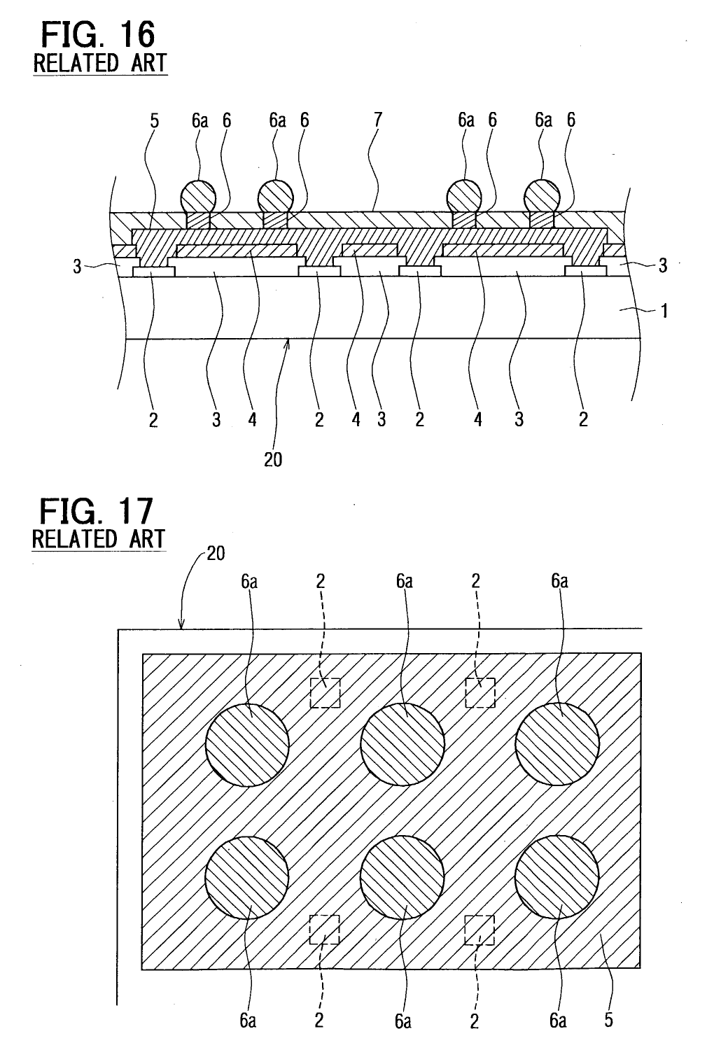

A semiconductor device as a third embodiment illustrated in FIG. 16 is similar in structure to those of the first or second embodiment except that a wiring pattern (areal wiring) of the semiconductor device has a slit. This will be explained later. FIG. 17 is a schematic plan view, and illustrates the physical relationship among a wiring pattern (areal wiring) 5, connection pads 2, and bump electrodes 6a. As illustrated in FIG. 17, the wiring pattern 5 is so designed that a plurality of the connection pads 2 which handle the same potential and a plurality of the bump electrodes 6a corresponding thereto are encircled therewith.

However, this semiconductor device poses a problem: the thermal stress produced by the difference in coefficient of thermal expansion between, for example, the wiring pattern 5 and a sealing film 7 cracks the wiring pattern 5 or sealing film 7. In particular, produced thermal stress is concentrated on wiring patterns 5 and sealing films 7 positioned at a peripheral portion of a semiconductor substrate 1. As a result, cracking in the wiring patterns 5 and the sealing films 7 becomes remarkable.

To cope with this, the third embodiment is intended to suppress cracking due to stress in a semiconductor device having wiring and bump electrodes connected with connection pads on a semiconductor substrate.

Referring to the drawings, a case where the semiconductor device in the third embodiment is applied to a semiconductor device of CSP (Chip Size Package) structure will be described below.

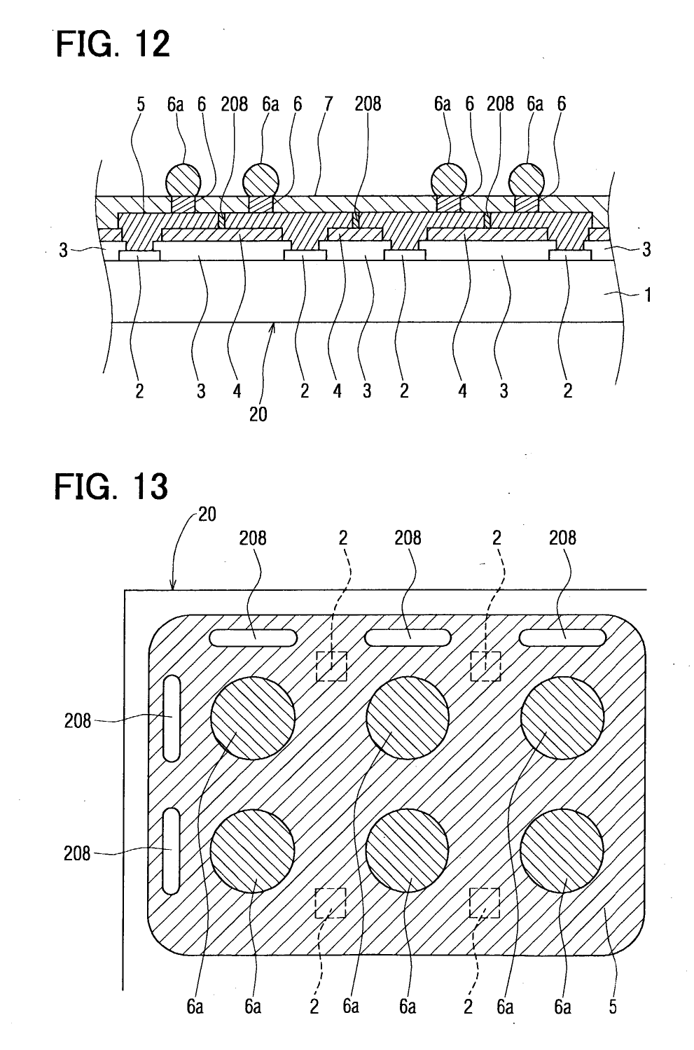

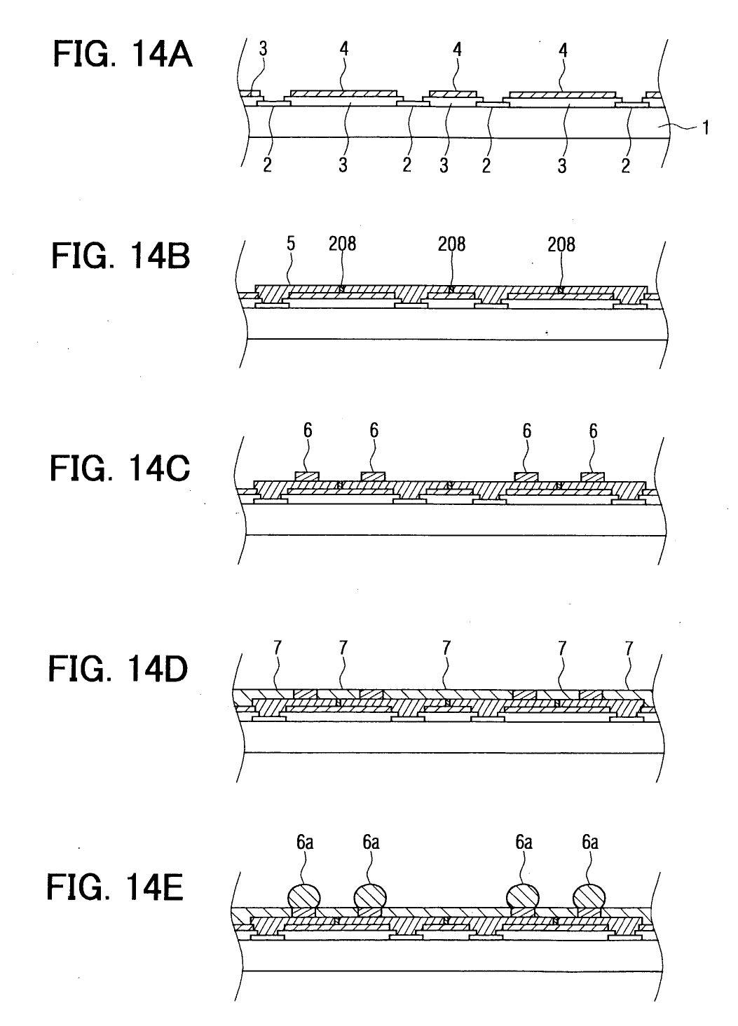

FIG. 12 illustrates the cross-sectional structure of the semiconductor device 20 in the third embodiment. FIG. 13 shows a schematic plan view of the semiconductor device 20, and FIGS. 14A to 14E illustrate a manufacturing method for the semiconductor device 20. In the FIG. 13, a resin film 7 is omitted.

Here, referring to FIGS. 14A to 14E, a manufacturing process for the semiconductor device 20 in this embodiment. This manufacturing process is similar to that for the first embodiment illustrated in FIGS. 3A to 3E.

However, there is a difference between both the processes: this wiring pattern 5 is formed by applying and curing photoresist for conductor layer, patterning it using photolithography, and then subjecting the areas opened by the resist to electrolytic plating. At this time, the resist is locally left in the opening patterns in the resist, and thereby the slits 208 are formed in the wiring pattern 5. The slits 208 are preferably positioned at the peripheral parts of the wiring patterns 5 located at the peripheral part of the semiconductor substrate 1.

Subsequently, for example, epoxy resin is applied to the entire surface of the semiconductor substrate 1 and is thereafter cured to form a sealing film 7 so that electrodes 6 are covered therewith, as illustrated in FIG. 14D. At this time, the epoxy resin is also applied to the interior of the slits 208 formed in the wiring pattern 5, and thus the sealing film 7 is formed in the slits 208 as well.

In the above case, the wiring pattern 5 for connecting the bump electrodes 6a with the connection pads 2 positioned between the bump electrodes 6a and the peripheral edge is so designed that a plurality of the connection pads 2 handling the same potential and a plurality of the bump electrodes 6a corresponding thereto are encircled therewith. In this case, the area of the wiring pattern 5 is increased, and this poses a problem that thermal stress produced by the difference in coefficient of thermal expansion between, for example, the wiring pattern 5 and the sealing film 7 cracks the wiring pattern 5 or the sealing film 7.

To cope with this, in this embodiment, the wiring pattern 5 so designed that the bump electrodes 6a and the connection pads 2 are encircled therewith is provided with the slits 208, as illustrated in FIG. 13. In this embodiment, five rectangular slits 208 whose corners are chamfered (rounded) are formed in the wiring pattern 5 so that the slits are kept away from the positions of the connection pads 2 and the bump electrodes 6a.

Thus, even if thermal stress is produced by the difference in coefficient of thermal expansion between the wiring pattern 5 and the sealing film 7, the produced thermal stress is dispersed and relaxed by the slits 208. As a result, cracking in the wiring pattern 5 and the sealing film 7 due to thermal stress is suppressed.

The above-mentioned thermal stress is concentrated on wiring patterns 5 and sealing films 7 positioned at the peripheral part of a semiconductor substrate 1. Cracking thereby becomes remarkable in the wiring patterns 5 and the sealing films 7 positioned at the peripheral part.

To cope with this, in this embodiment, at least wiring patterns 5 positioned at the peripheral edge of a semiconductor substrate 1 is provided with slits 8 which are positioned at the peripheral part of the wiring pattern and between connection pads 2 and the peripheral part. Thus, the concentration of stress on the wiring patterns 5 and the sealing films 7 positioned at the peripheral edge of the semiconductor substrate 1 is relaxed. As a result, cracking in wiring patterns 5 and sealing films 7 due to stress is suppressed.

Furthermore, in this embodiment, a wiring pattern 5 so designed that bump electrodes 6a and connection pads 2 are encircled therewith is formed. In this case, the concentration of current and stress on the corners of the wiring pattern 5 is suppressed by chamfering (rounding) the corners of the wiring pattern 5, as illustrated in FIG. 13. Thus, deterioration in the wiring patterns 5 due to the concentration of current and cracking due to the concentration of stress are suppressed. Furthermore, chamfering may be performed not only on the corners of a wiring pattern 5 but also on the corners of slits 208 formed in the wiring pattern 5, as illustrated in FIG. 13. Thus, the same effect as cases where the corners of a wiring pattern 5 are chamfered is produced.

The present invention is not limited to the above-mentioned embodiment and is applicable to a variety of modes.

In the above embodiment, six bump electrodes 6a are formed for four connection pads 2, as illustrated in FIG. 13. However, the numbers of the connection pads 2 and the bump electrodes 6a are not limited to those in the above embodiment.

Furthermore, in the above embodiment, five rectangular slits 208 are formed in a wiring pattern 5, as illustrated in FIG. 13. However, the shape and number of slits 208 are not limited to those in the above embodiment. Slits 208 may be formed as appropriate taking into account increase in the wiring resistance of the wiring pattern 5 and the stress relaxation effect of the slits 208.

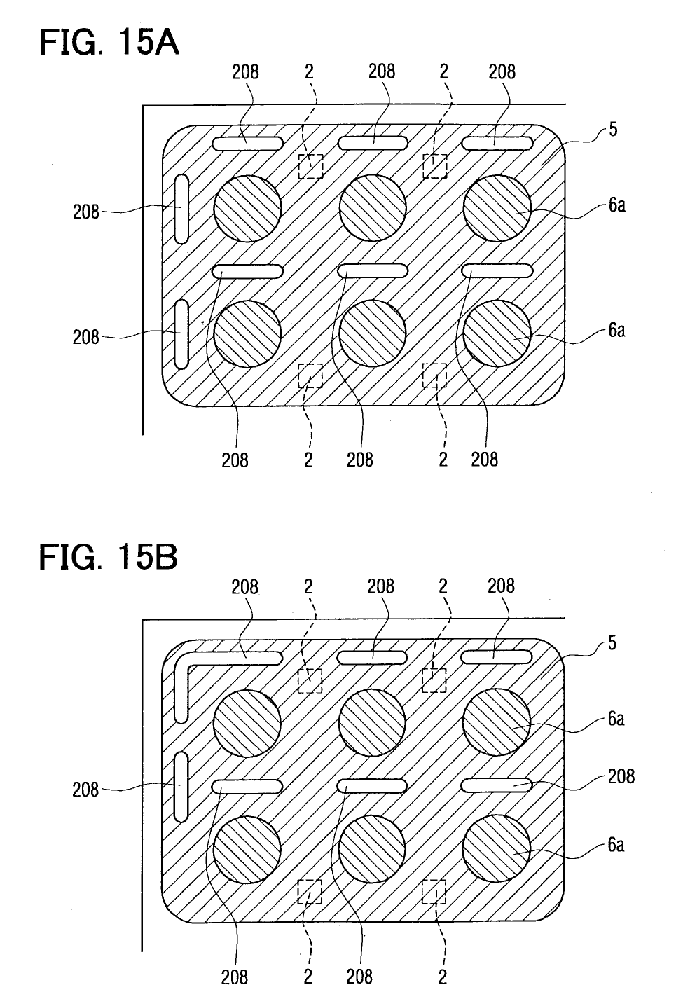

Furthermore, in the above embodiment, slits 208 are formed only at the peripheral parts of wiring patterns 5 positioned at the peripheral edge of a semiconductor substrate 1, as illustrated in FIG. 13. However, slits 208 may be formed in the central part of a wiring pattern 5, that is, between bump electrodes 6a, as illustrated in FIG. 15A. Or, slits 208 may be formed at the corners of a wiring pattern 5, as illustrated in FIG. 15B. By the way, it is preferable that slits 208 should be formed in other areas than the area between a connection pad 2 and a bump electrode 6a, taking the wiring resistance of the wiring pattern 5 into account.

### Fourth Embodiment

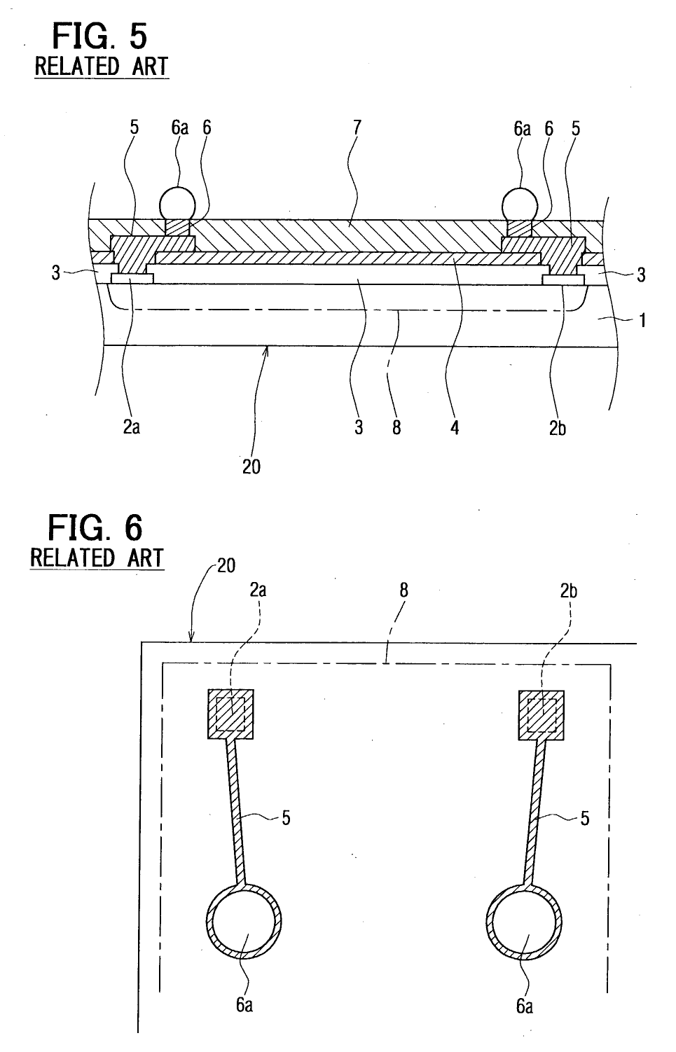

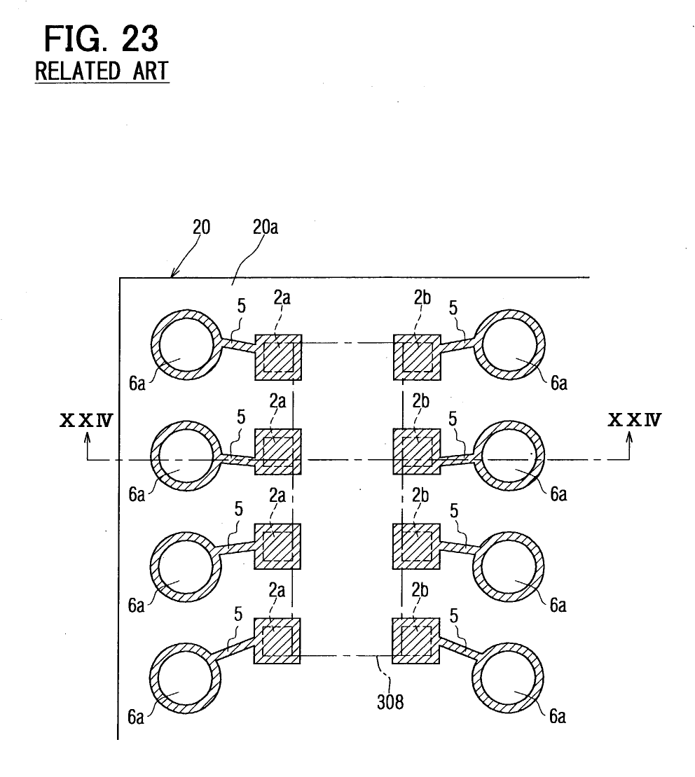

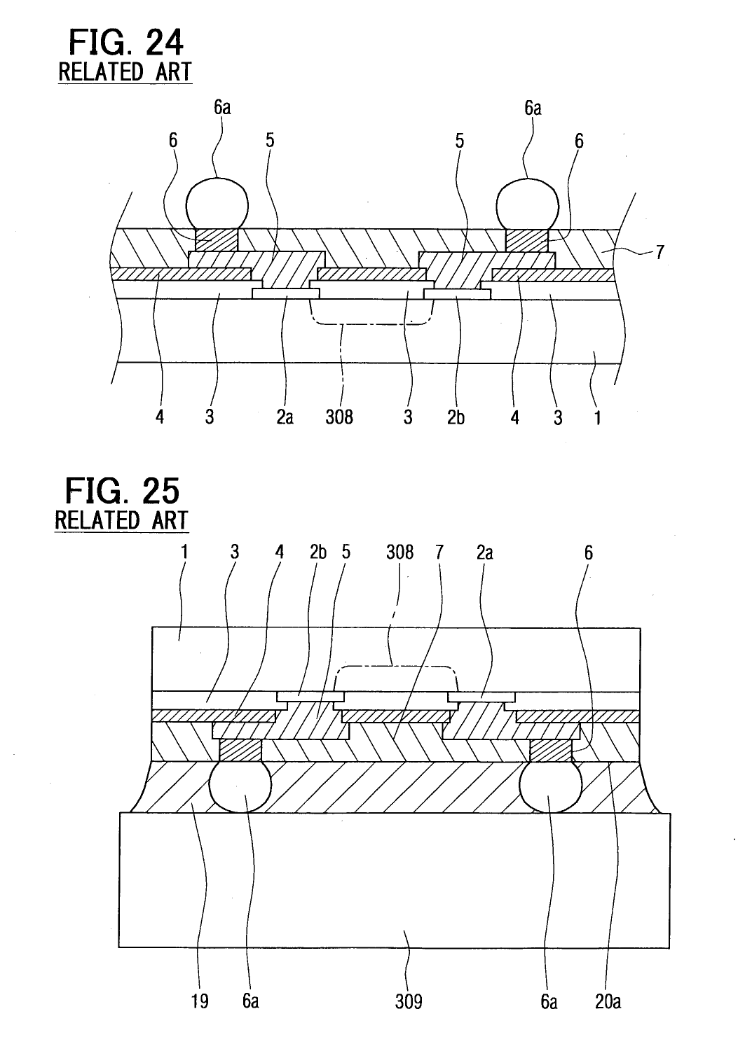

First, related arts will be described. FIGS. 23, 24, and 25 illustrate cases where the CSP structure is applied to a semiconductor device, for example, a power device where relatively large current is passed. FIGS. 23 and 24 are similar to FIGS. 5 and 6 except that a heater element 308 is formed.

Here, a case where a heater element (indicated as region 308), such as a power transistor, is formed on the surface of a semiconductor substrate 1 will be considered. This heater element 308 is electrically connected with bump electrodes 6a through source pads 2a, drain pads 2b, wiring patterns 5, and electrodes 6, and is then to be connected with the outside.

A semiconductor device 20 is positioned so that the bump electrodes 6a thereof are connected with wiring, pads, and the like (not shown) on a mounting board 309 and installed on the mounting board 309, as illustrated in FIG. 25. Then, the bump electrodes 6a are melted by heating and the semiconductor device is thereby mounted on the mounting board 309. After the semiconductor device 20 is mounted, underfill 19 composed of thermosetting resin or the like is filled in between the semiconductor device 20 and the mounting board 309 to protect the bump electrodes 6a against impact, fatigue, and the like.

However, conventionally, the bump electrodes 6a are placed on the face 20a of the semiconductor device 20 in correspondence with the area around the heater element 308. Only the underfill 19 is interposed between the major part of the heater element 308 formation region and the mounting board 309.

As a result, heat produced by the heater element 308 formed in a semiconductor substrate 1 is radiated only over a path leading to the mounting board 309 via the bump electrodes 6a. Therefore, the semiconductor device 20 is inferior in the properties of heat radiation and this leads to a problem that the characteristics of the heater element 308 and nearby elements are fluctuated by heat. This problem is remarkable especially in the central part of the heater element 308 where heat is apt to be confined.

To cope with this, the fourth embodiment is intended to enhance the properties of heat radiation of a semiconductor device which comprises a semiconductor substrate with a heater element formed therein and bump electrodes formed on one-side face of the semiconductor substrate and electrically connected with the heater element, and which is mounted on a mounting board.

Referring to the drawings, a case where the semiconductor device in this embodiment is applied to a semiconductor device of CSP (Chip Size Package) structure will be described below. In this embodiment, the CSP structure is applied to a semiconductor device, for example, a power device where relatively large current is passed.

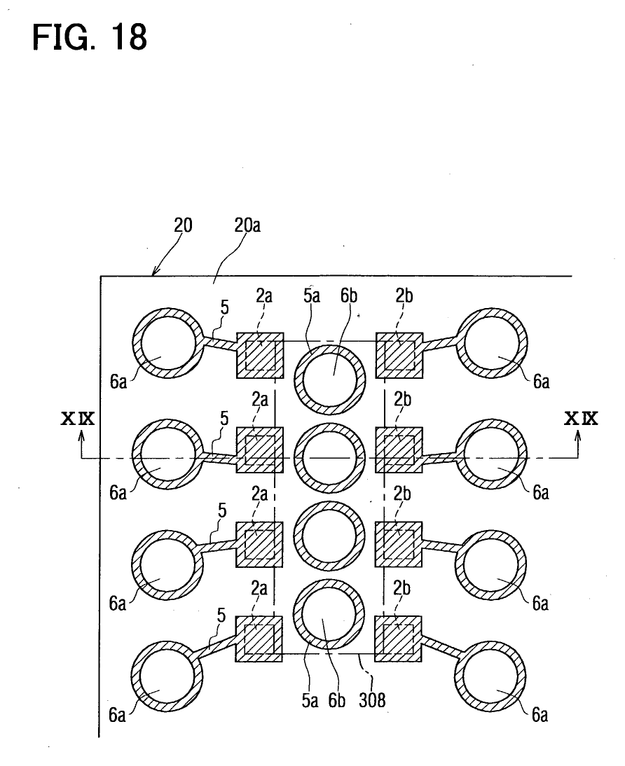

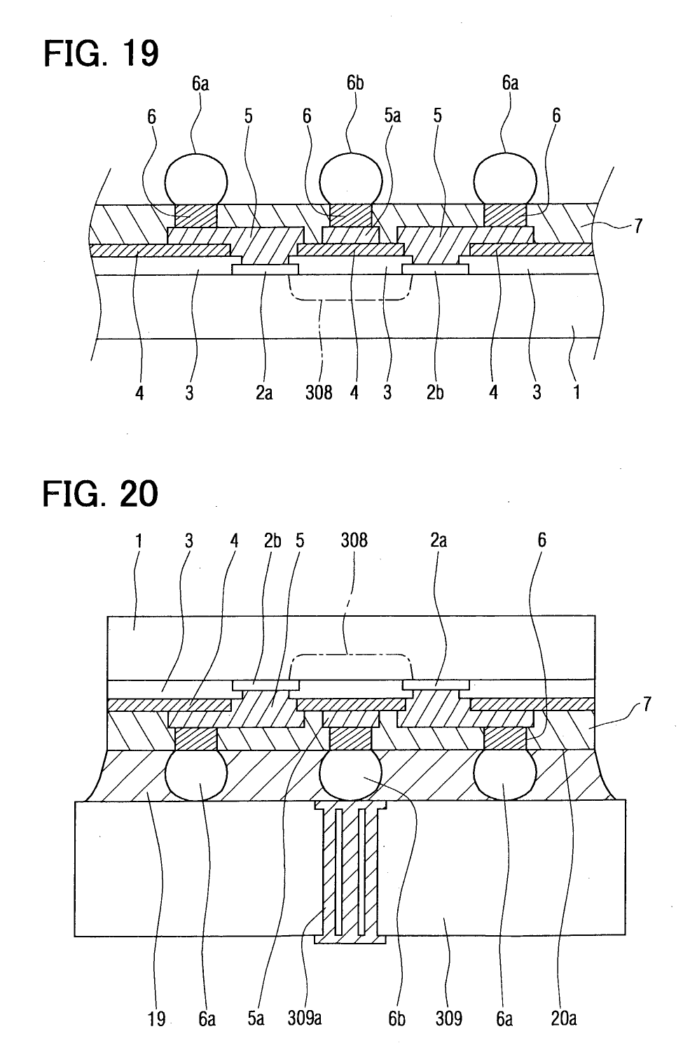

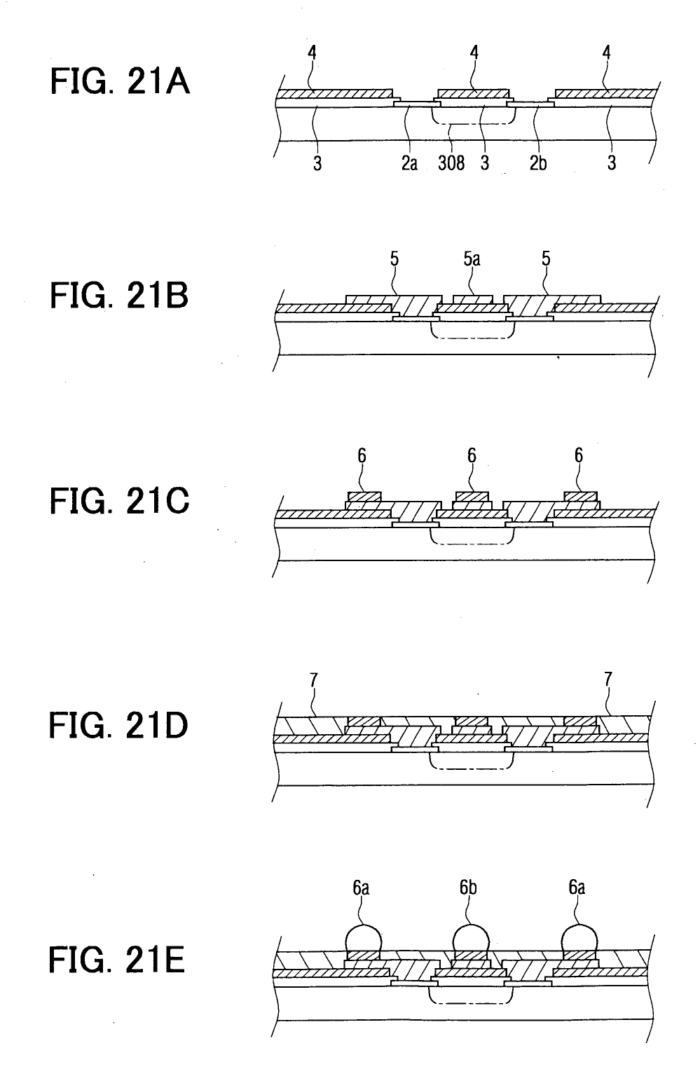

FIG. 18 illustrates the planar structure of a semiconductor device 20 in the fourth embodiment of the present invention, and FIG. 19 is a schematic sectional view taken along line XIX-XIX of FIG. 18. FIG. 20 illustrates the semiconductor device 20 illustrated in FIG. 19, as is mounted on a mounting board 309, and FIGS. 21A to 21E illustrate a manufacturing method for the semiconductor device 20. In FIG. 18, a sealing film 7 is omitted. This embodiment is similar to the first embodiment illustrated in FIGS. 1 and 2 in many points, and the description of these points is omitted.

A difference between the fourth embodiment and the first embodiment is that a heater element (indicated as region 308), such as a power transistor, is formed. This heater element 308 is electrically connected with bump electrodes 6a through source pads 2a, drain pads 2b, wiring patterns 5, and electrodes 6, and is to be connected with the outside.

Furthermore, dummy bumps 6b which are not connected with the heater element 308 are formed in the areas on the face 20a of the semiconductor device 20 with the bump electrodes 6a formed thereon, which areas correspond to the area with the heater element 308 formed therein. A passivation film 3, an insulating film 4, wiring patterns 5a for dummy bumps 6b, and electrodes 6 are placed between the semiconductor substrate 1 and the dummy bumps 6b.

The semiconductor device 20 in this embodiment is positioned so that the bump electrodes 6a are connected with wiring, pads, and the like (not shown) on a mounting board 309 and installed on the mounting board 309, as illustrated in FIG. 20. Then, the bump electrodes 6a and the dummy bumps 6b are melted by heating and the semiconductor device is thereby mounted on the mounting board 309.

In this embodiment, wiring 309a for heat radiation is formed as a heat radiating means in the area in the mounting board 309 corresponding to the dummy bumps 6b. This wiring 309a for heat radiation is so formed that the wiring penetrates the mounting board 309 and extends from the face thereof with the semiconductor device 20 mounted thereon to the face on the opposite side.

After the semiconductor device 20 is mounted, underfill 19 composed of thermosetting resin or the like is filled in between the semiconductor device 20 and the mounting board 309 to protect the bump electrodes 6a against impact, fatigue, and the like.

Here, referring to FIGS. 21A to 21E, a manufacturing process for the semiconductor device 20 in this embodiment will be described. The manufacturing process is substantially the same as the manufacturing process in the first embodiment illustrated in FIGS. 3A to 3E, and the same description will be omitted.

First, the heater element 308, such as a power transistor, is formed in the surface of the semiconductor substrate 1, as illustrated in FIG. 21A.

After resist is stripped off, wiring patterns 5 composed of copper, aluminum, or the like are formed on the source pads 2a and the drain pads 2b exposed in openings formed in the insulating film 4, as illustrated in FIG. 21B. Furthermore, wiring patterns 5a for dummy bumps are formed on the insulating film 4 formed in the position corresponding to the heater element 308.

The bump electrodes 6a are formed and simultaneously the dummy bumps 6b which are not connected with the heater element 308 are formed in the area on the surface of the sealing film 7 corresponding to the area with the heater element 308 formed therein, as illustrated in FIG. 21E. Thus, the semiconductor device 20 as illustrated in FIG. 19 is completed.

Where a heater element 308, such as a power transistor, is formed in the surface of a semiconductor substrate 1, as mentioned above, the bump electrodes 6a are conventionally placed on the face 20a of the semiconductor device 20 in correspondence with the area around the heater element 308. Only the underfill 19 is interposed between the major part of the heater element 308 formation region and the mounting board 309.

As a result, heat produced by the heater element 308 formed in the semiconductor substrate 1 is radiated only over a path leading to the mounting board 309 via the bump electrodes 6a. Therefore, the semiconductor device 20 is inferior in the properties of heat radiation and this leads to a problem that the characteristics of the heater element 308 and nearby elements are fluctuated by heat. This problem is remarkable especially in the central part of the heater element 308 where heat is apt to be confined.

This embodiment is characterized by the following: the dummy bumps 6b which are not connected with the heater element 308 are formed in the area on the face 20a of the semiconductor device 20 with the bump electrodes 6a formed therein, corresponding to the area with the heater element 308 formed therein, as illustrated in FIGS. 18, 19, and 20. In this embodiment, four dummy bumps 6b are formed on the face 20a of the semiconductor device 20 with the bump electrodes 6a formed thereon, as illustrated in FIG. 18.

Thus, heat produced by the heater element 308 formed in the semiconductor substrate 1 is radiated not only over the path leading to the mounting board 309 via the bump electrodes 6a. The heat is radiated also over an addition path leading to the mounting board 309 via the dummy bumps 6b. As a result, the properties of heat radiation of the semiconductor device 20 can be enhanced, and thus fluctuation in the characteristics of the heater element 308 due to heat is suppressed.

These dummy bumps 6b can be formed at the same time as the bump electrodes 6a which are external electrode terminals, and thus the properties of heat radiation of the semiconductor device 20 can be enhanced without increase in the number of process steps.

Furthermore, in this embodiment, wiring 309a for heat radiation is formed as a heat radiating means in the area in the mounting board 309 corresponding to the dummy bumps 6b, as illustrated in FIG. 20. This wiring 309a for heat radiation is so formed that the wiring penetrates the mounting board 309 and extends from the face thereof with the semiconductor device 20 mounted thereon to the face on the opposite side.

Thus, heat produced by the heater element 308 can be externally radiated from the dummy bumps 6b through the wiring 309a for heat radiation formed in the mounting board 309. As a result, the properties of heat radiation of the semiconductor device 20 can be enhanced, and fluctuation in the characteristics of the heater element 308 due to heat can be further suppressed.

The present invention is not limited to the above-mentioned embodiment and is applicable to a variety of modes.

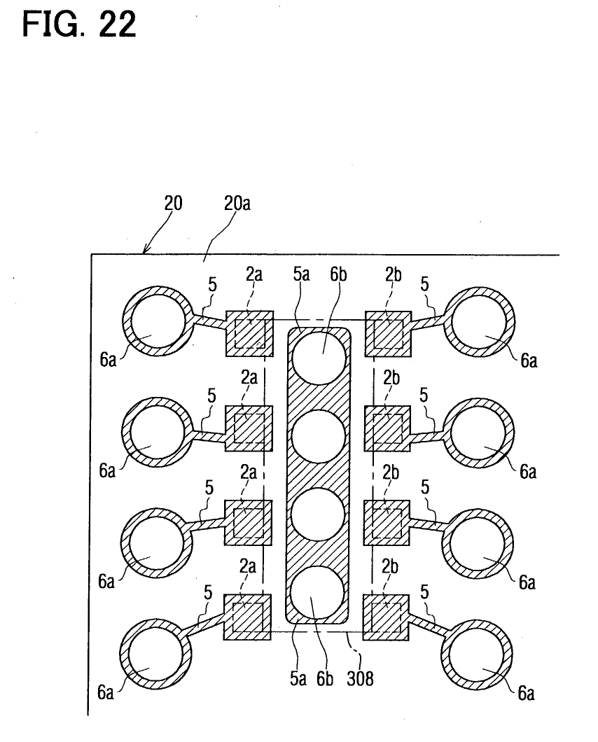

In the above embodiment, wiring patterns 5a for dummy bumps 6b are individually formed for a plurality of dummy bumps 6b. However, wiring 5a for dummy bumps 6b may be formed so that a plurality of dummy bumps 6b are encircled therewith, as illustrated in FIG. 22. This increases the area of the wiring 5a for dummy bumps 6b. As a result, the radiation of heat produced by the heater element 308 is facilitated and fluctuation in the characteristics of the heater element 308 can be further suppressed. In this case, it is preferable that the corners of the wiring 5a for dummy bumps should be chamfered.

Furthermore, in the above embodiment, four spherical dummy bumps 6b are formed on a heater element 308. However, the shape and the number of the dummy bumps 6b are not limited to those in the above embodiment. Furthermore, the dummy bumps 6b need not be identical in outer dimensions and shape with the bump electrodes 6a.

### Fifth Embodiment

First, related arts will be described. FIGS. 30 and 31 illustrate a case where the CSP structure is applied to a semiconductor device, such as a power device where relatively large current is passed. A case where a plurality of heater elements, such as power transistors, (indicated as regions 408) are formed in the surface of a semiconductor substrate 1 will be considered. These heater elements 408 are electrically connected with bump electrodes 6a through source pads 2a, drain pads 2b, wiring patterns 5, and electrodes 6, and are to be connected with the outside.

However, conventionally, no consideration is given to the layout of heater elements 408, as illustrated in FIG. 31, and it is assumed that heater elements 408 are placed in a semiconductor substrate 1 in a concentrated manner.

In this case, heat produced by the heater elements 408 is concentrated in areas in the semiconductor substrate 1 with the heater elements 408 placed therein in a concentrated manner, and this impairs the properties of heat radiation. As a result, a problem arises that the characteristics of the heater elements 408 are fluctuated by heat.

To cope with this, this embodiment is intended to provide a layout of heater elements which enhances the properties of heat radiation of the heater elements.

Referring to the drawings, a case where the semiconductor device in the fifth embodiment is applied to a semiconductor device of CSP structure will be described.

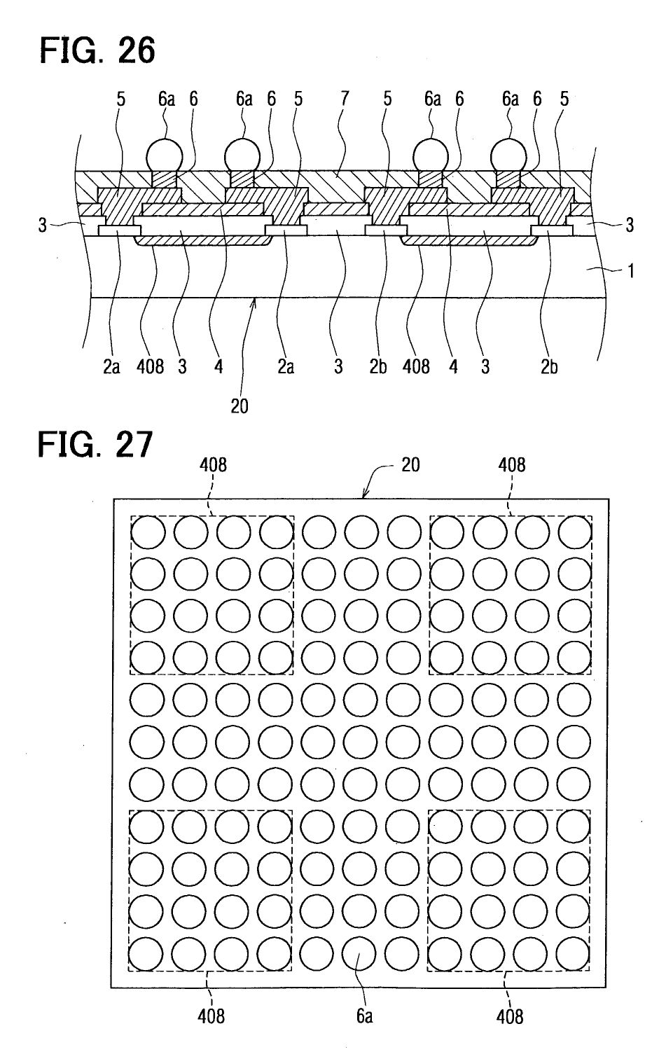

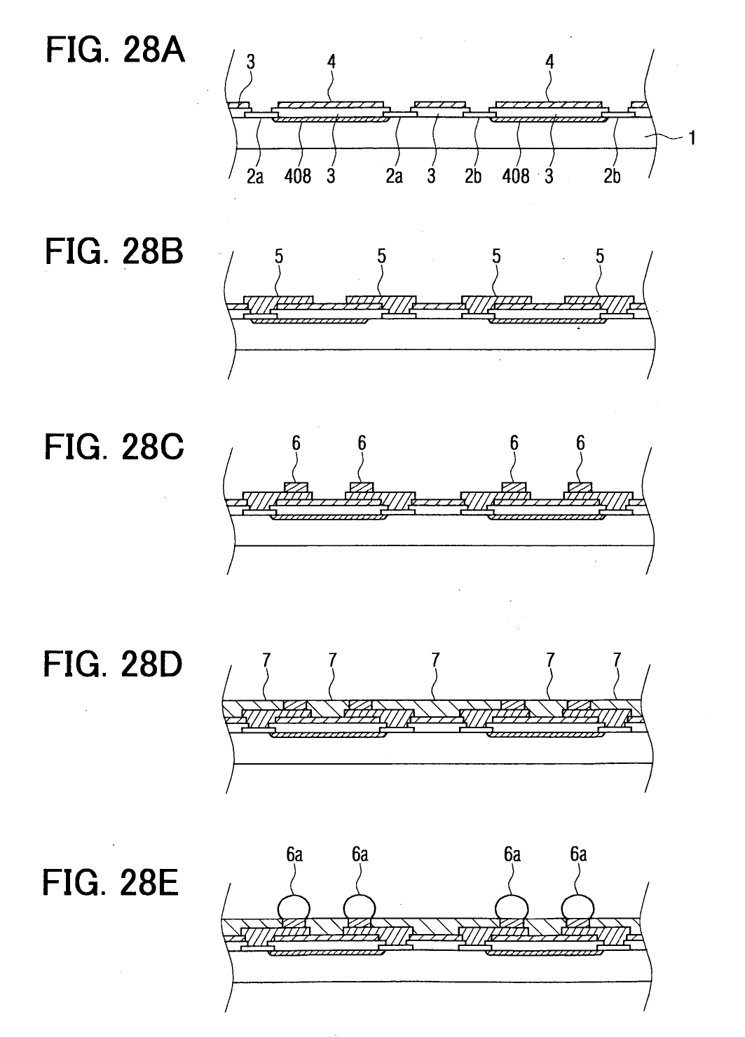

FIG. 26 illustrates schematic cross-sectional structure of a semiconductor device 20 in the fifth embodiment of the present invention. FIG. 27 is a schematic plan view of the semiconductor device 20, and FIGS. 28A to 28E illustrate a manufacturing method for the semiconductor device 20. In FIG. 27, a resin film 7 is omitted.

A plurality of heater elements, such as power transistors, (indicated as regions 408) are formed in the surface of a semiconductor substrate 1. These heater elements 408 are electrically connected with bump electrodes 6a through source pads 2a, drain pads 2b, wiring patterns 5, and electrodes 6, and are to be connected with the outside.

FIGS. 28A to 28E illustrate a manufacturing process for the semiconductor device 20 in this embodiment. This process is similar to the manufacturing process in the first embodiment illustrated in FIGS. 3A to 3E except that the heater elements 408 are formed, and thus the description of the manufacturing process will be omitted.

In this embodiment, a plurality of heater elements, such as power transistors, are formed in the surface of a semiconductor substrate 1. However, conventionally, no consideration is given to the layout of heater elements 408 and it is assumed that heater elements 408 are placed in a semiconductor substrate 1 in a concentrated manner.

In this case, heat produced by the heater elements 408 is concentrated in areas in the semiconductor substrate 1 with the heater elements 408 placed therein in a concentrated manner, and this impairs the properties of heat radiation there. As a result, a problem arises that the characteristics of the heater elements 408 are fluctuated by heat.

To cope with this, this embodiment is characterized by that heater elements 408 formed in a semiconductor substrate 1 are uniformly laid out at equal intervals, as shown in FIG. 27. More specifically, bump electrodes 6a are laid out in a matrix pattern and heater elements 408 are laid out so that the bump electrodes 6a placed between the adjacent heater elements 408 are equal in number. In this embodiment, the heater elements 408 are laid out so that the number of the bump electrodes 6a placed between the adjacent heater elements 408 is three.

Thus, heat produced by the heater elements 408 formed in the semiconductor substrate 1 is dispersed, and the concentration of heat on the semiconductor substrate 1 is suppressed. As a result, the properties of heat radiation of the semiconductor substrate 1 can be enhanced, and fluctuation in the characteristics of the heater elements 408 due to concentrated heat can be suppressed.

The present invention is not limited to the above-mentioned embodiment and is applicable to a variety of modes.

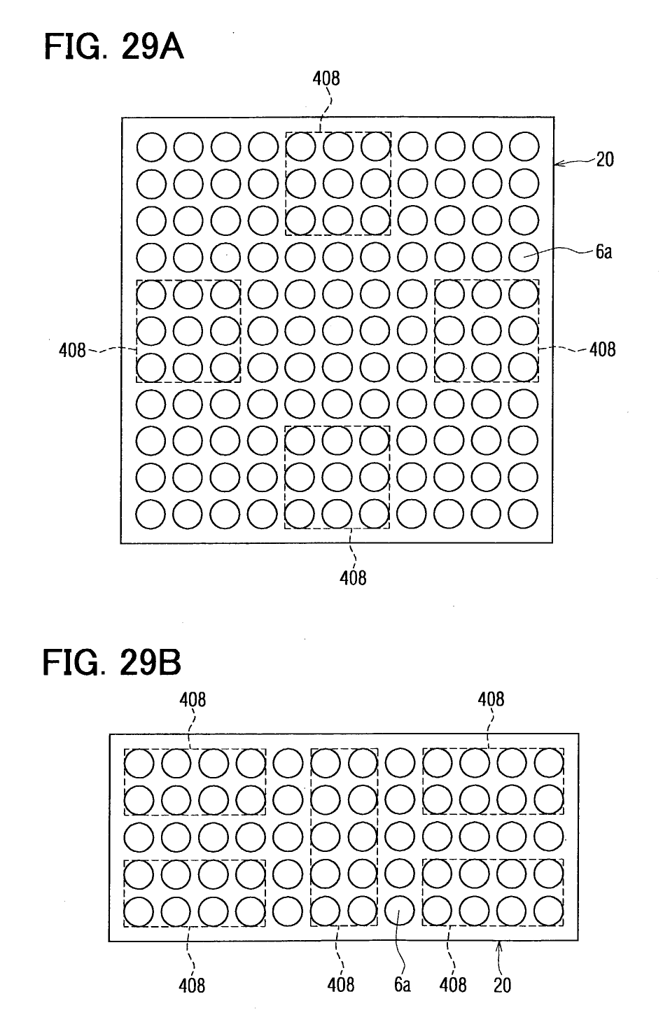

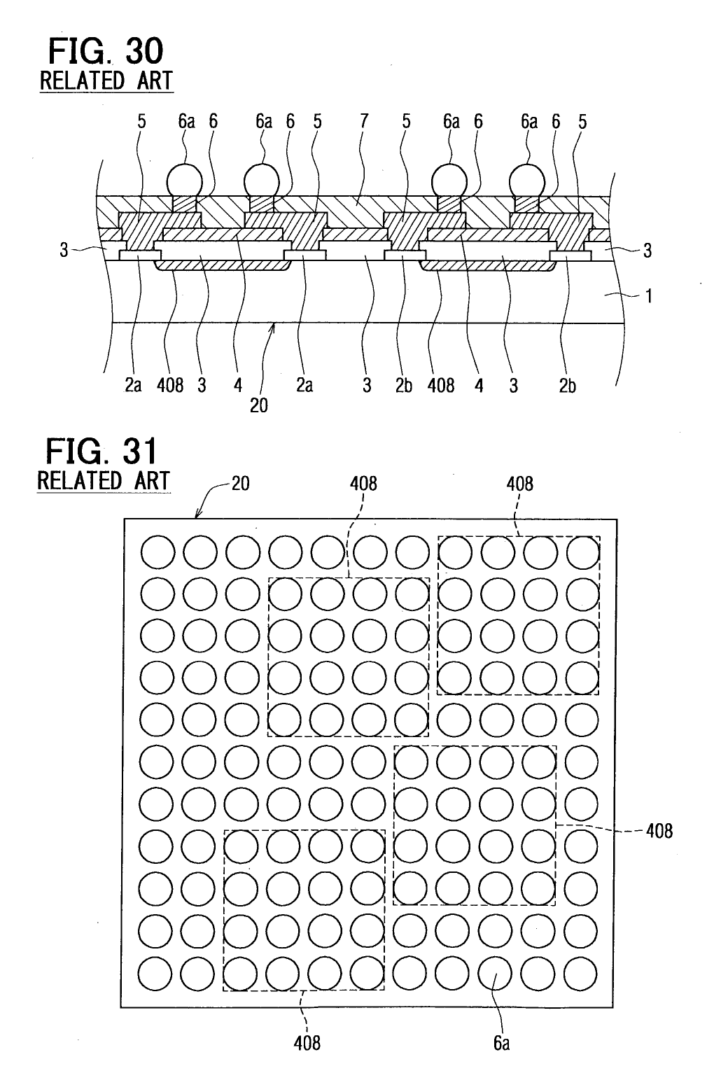

In the above embodiment, the heater elements 408 are placed at the four corners of the semiconductor substrate 1. However, the heater elements 408 only have to be uniformly laid out at equal intervals, as illustrated in FIG. 29A.

Furthermore, in the above embodiment, square heater elements 408 are placed in four places. However, the shape and the number of the heater elements 408 are not limited to those in the above embodiment, and rectangular heater elements 408 may be placed in five places, as illustrated in FIG. 29B.

### Sixth Embodiment

First, related arts will be described.

A multiple-unit IC package is defined as a package where electric elements, such as power elements, including LDMOSs (Lateral DMOSs), VDMOSs (Vertical DMOSS), and IGBTs (Insulated Gate Bipolar Transistors), CMOSs other than these power elements, bipolar transistors, resistance elements, and capacitor elements, are formed on a semiconductor chip composed of silicon or the like.

A plurality of bumps arranged with a specified pitch are formed on a one-side face of the chip, and electrical continuity is provided between these bumps and the above-mentioned elements. These IC packages are mounted on a wiring board or the like through the bumps, and are also called CSP (Chip Size Package).

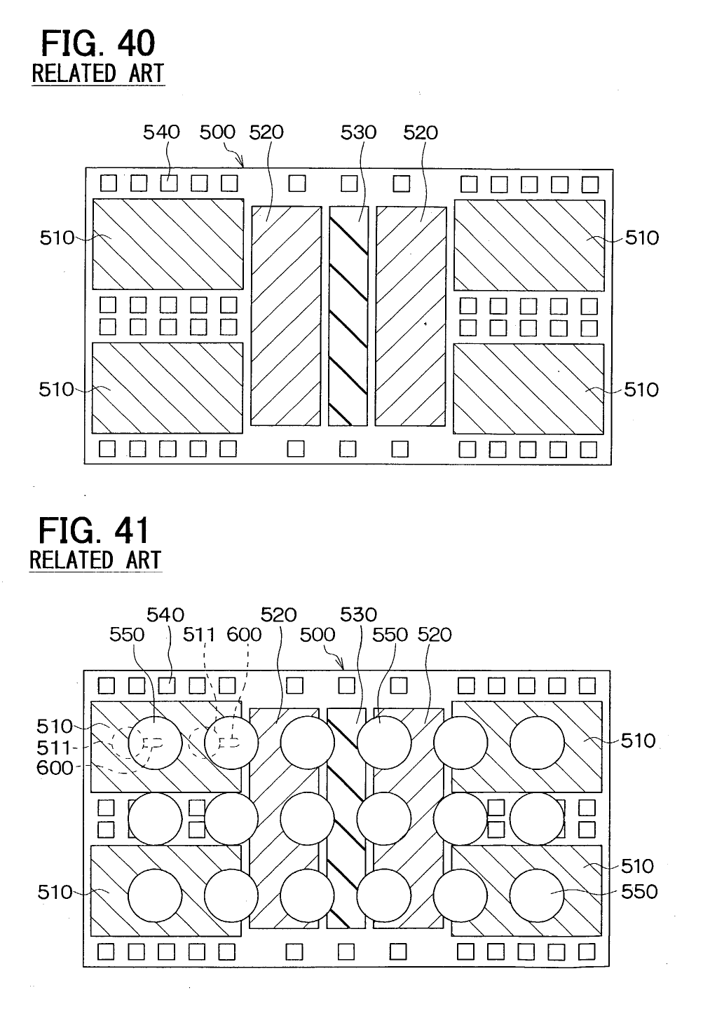

By the way, conventionally, the layout pattern of the elements in chip and the layout pattern of the bumps are separately designed. FIG. 40 is a schematic plan view illustrating an example of the layout pattern of elements in chip in a conventional multiple-unit IC package.

Various elements, such as power element portions 510, bipolar circuit portions 520 comprising bipolar transistors, and a CMOS circuit portion 530 comprising CMOS, different in size and shape are laid out in a chip 500 in a specified pattern.

FIG. 41 is a schematic plan view illustrating the chip 500 in FIG. 40 mounted with a plurality of bumps 550. A plurality of bumps 550 are arranged in a matrix pattern with a specified pitch to efficiently lay out a large number of the bumps 550.

Conventionally, the layout of elements and the layout of bumps are designed independent of each other, as mentioned above. Therefore, there may be places where the above circuit portions 510, 520, and 530 comprising various elements are misaligned with bumps 550.

In this case, usually, wiring pattern layers 600 are formed between the lead-out electrodes 511 of elements in the circuit portions and the bumps 550 to provide electrical continuity, as indicated by broken lines in FIG. 41. Examples of such wiring pattern layers include that disclosed in JP-A-2001-144223.

However, if the lead-out electrodes of elements and bumps are excessively misaligned with each other, the length of wiring pattern layers is accordingly increased, which leads to increase in wiring resistance between an element and a bump. Of elements formed in a chip, power elements pass relatively large current. Therefore, increase in wiring resistance increases on-resistance, and this greatly affects the characteristics of elements. Hence, increase in wiring resistance is undesirable.

To cope with this, this embodiment is intended to significantly reduce the wiring resistance between elements, including power elements, and corresponding bumps in a multiple-unit IC package where the power elements and the other electric elements are formed in one chip.

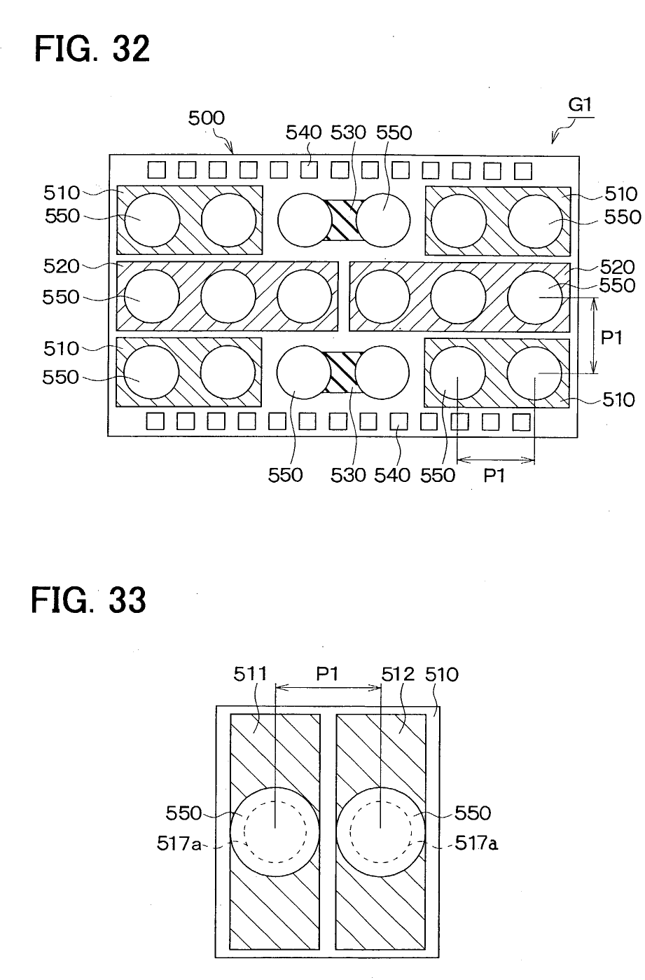

Referring to the drawings, this embodiment will be described below. FIG. 32 is a schematic plan view of a multiple-unit IC package G1 in this embodiment of the present invention, as viewed from the bump formation side. Of the drawings listed in this specification, plan views are hatched to facilitate identification and this hatching does not present cross sections.

This multiple-unit IC package G1 includes a chip 500 comprising a semiconductor substrate, such as a silicon substrate. In the chip 500, a plurality of elements, different in kind, are formed in different regions on a kind-by-kind basis, and the elements of the same kind constitute the respective circuit portions 510, 520, and 530.

A plurality of the elements different in kind are power elements where large current is passed, and electric elements other than these power elements. Power elements include LDMOSs, VDMOSs, and IGBTs. In this example, the power elements are constituted of LDMOSs, and a plurality of LDMOSs are aggregated to constitute circuits. The power element portions 510 are thus formed.

Electric elements other than power elements include CMOSs, bipolar transistors, resistance elements, capacitor elements, and the like. In FIG. 32, bipolar circuit portions 520 constituted of bipolar transistors and CMOS circuit portions 530 constituted of CMOSs are depicted.

Furthermore, inspecting pads 540 for the inspection of these circuit portions 510 to 530 are formed on the chip 500. On a one-side face of the chip 500, a plurality of bumps 550 are laid out in a matrix pattern with a specified arrangement pitch P1. This arrangement pitch P1 may be set to, for example, several tenths of a millimeter or so.

The layout pattern of the circuit portions 510 to 530 comprising a plurality of the above-mentioned elements, different in king, is designed according to this arrangement pitch P1 of the bumps 550. That is, the individual circuit portions 510 to 530 are arranged in, for example, two or three times the arrangement pitch P1, as illustrated in FIG. 32.

More specifically, the circuit portions are so arranged that the lead-out electrodes of the elements in the circuit portion 510 to 530 are identical in position with the bumps 550 corresponding to the lead-out electrodes. FIG. 33 is an enlarged plan view of a power element portion 510 in FIG. 32. In FIG. 33, the lead-out electrodes 511 and 512 of the power element portion 510 and the bumps 550 corresponding thereto are positioned so that one electrode and one bump overlap each another.

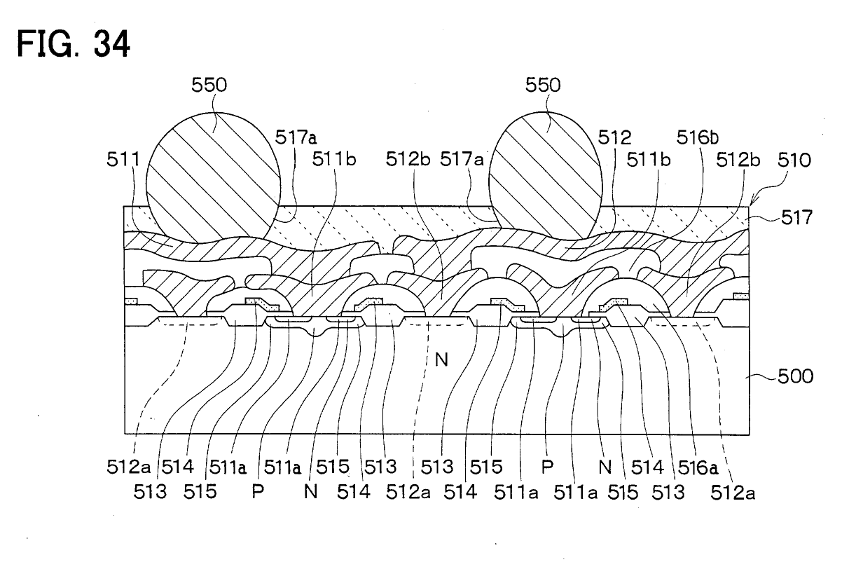

The structure of connection between the bumps 550 and the elements will be described taking as an example the power element portion 510 constituted of LDMOSs in this embodiment. FIG. 34 is a partial schematic sectional view of the power element portion 510 taken in a direction of chip 500 thickness.

In the example illustrated in FIG. 34, a plurality of transistor elements are placed in plane on the surface of a N-type silicon substrate as a chip 500. Each of the transistor elements has common MOS transistor configuration, and is insulated and isolated by a LOCOS oxide film 513.

That is, when voltage is applied to the gate electrode 514, the conductivity type of the channel 515 is inverted, and current is let to flow from the source 511a to the drain 512a. The gate electrode 514, source electrode 51b, and drain electrode 512b of each transistor element are insulated and isolated by a first insulating layer 516a and a second insulating layer 516b laminated from bottom in this order.

On the second insulating layer 516b, the lead-out electrode 511 for source electrode and the lead-out electrode 512 for drain electrode are formed as the lead-out electrodes 511 and 512 of the power element portion 510 illustrated in FIG. 33 as well. These lead-out electrodes 511 and 512 are composed of aluminum or the like.

Openings are formed at appropriate points on the second insulating layer 516b. Thereby, in the power element portion 510, the source electrodes 511b of the MOS transistors are integrated together into the lead-out electrode 511 for source electrode for conduction and the drain electrodes 512b are integrated together into the lead-out electrode 512 for drain electrode for conduction.

The bumps 550 are placed directly above the individual lead-out electrodes 511 and 512, and continuity is provided between the lead-out electrodes 511 and 512 and the respective bumps 550. An insulating film 517 comprising a silicon oxide film, a polyimide layer, or the like is formed on the lead-out electrodes 511 and 512. Continuity between the source electrode 511b and the drain electrode 512b of each MOS transistor and the lead-out electrodes 511 and 512 is provided through openings 517a formed in the insulating film 517.

In this example of the power element portion 510, the bumps 550 are placed directly above the lead-out electrodes of the electric elements, and continuity is provided between the bumps 550 and the lead-out electrodes. This is the same with other electric elements, that is, the bipolar circuit portions 520 and the CMOS circuit portions 530 in this example. The bumps 550 are placed directly above the lead-out electrodes of the electric elements in each circuit portion 520 and 530, and continuity is provided between the bumps 550 and the respective lead-out electrodes.

The laminated structure of lead-out electrodes with an insulating layer interposed, as illustrated in FIG. 34 is in accordance with the structure disclosed in JP-A-H7-263665 for which the applicant of the present invention applied. However, in this embodiment, the lead-out electrodes of elements need not be of such laminated structure and may be of single layer structure in some elements.

Such a multiple-unit IC package G1 can be manufactured as follows: circuit portions 510, 520, and 530 comprising various elements are formed on a chip 500 by a known semiconductor process technology; and then bumps 550 are formed directly above the lead-out electrodes of the circuit portions 510 to 530 by printing, vapor deposition, solder ball method, or the like. The positions in which the elements are formed are matched with the layout pattern of the bumps 550 previously designed.

As mentioned above, the multiple-unit IC package G1 in this embodiment is characterized by that the layout pattern of power elements and electric elements is designed in accordance with the arrangement pitch P1 of bumps 550. More specifically, the lead-out electrodes of the elements, such as power elements and electric elements, and the bumps 550 corresponding to the lead-out electrodes are so arranged that the lead-out electrodes are identical in position with the bumps.

Thus, the elements are placed on the chip 500 according to the arrangement pitch P1 of the bumps 550. Accordingly, the positions of the elements can be matched with the positions of the corresponding bumps 550 as much as possible. As a result, it is obviated to form wiring pattern layers, which are required in conventional cases, between the lead-out electrodes of each element and the corresponding bumps 550.

Hence, with this embodiment, the wiring resistance between each element, including power elements, and a bump 550 corresponding to the element is significantly reduced in a multiple-unit IC package G1. In particular, in a power element where increase in the wiring resistance need be suppressed, the on-resistance thereof is reduced.

In case of an IC package where only electric elements of the same kind, not electric elements different in kind, are arranged on a chip, the arrangement of bumps is naturally matched with the arrangement of the elements.

This embodiment relates to IC packages where various electric elements, different in size and shape, are formed on the same chip. In such a case, with conventional structures and designs, misalignment is inevitable between elements and bumps. This embodiment is intended to solve this problem.

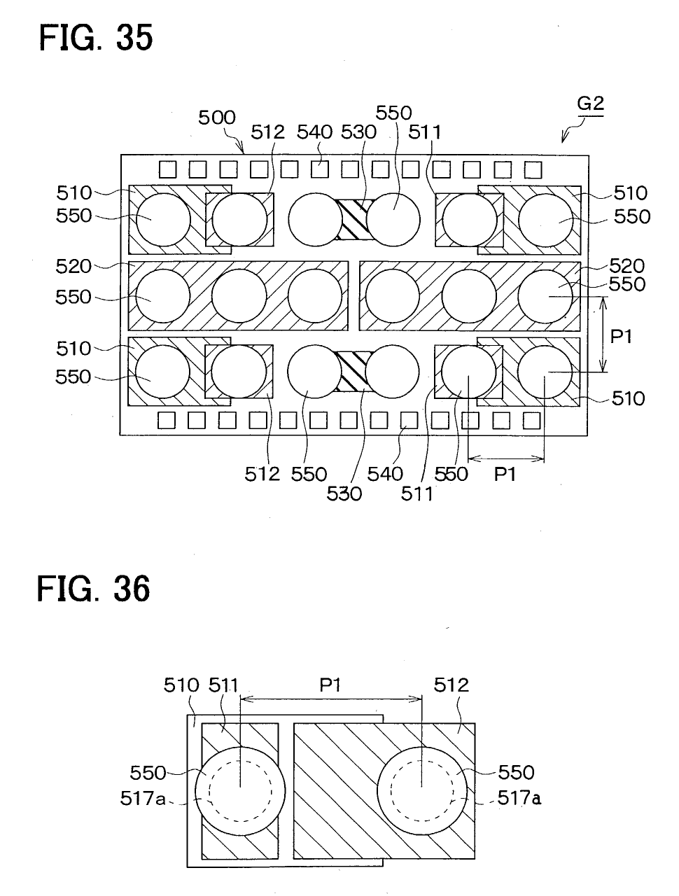

Various modifications to this embodiment will be described below. FIG. 35 is a schematic plan view of a multiple-unit IC package G2 as a first modification to this embodiment. FIG. 36 is an enlarged plan view of a power element portion 310 of the IC package in FIG. 35. The lead-out electrodes of power elements and other electric elements may be positioned so that part thereof is protruded from the respective circuit portions 510 to 530 constituted of these elements.

In the example illustrated in FIG. 35 and FIG. 36, some of the lead-out electrodes 512 of the power elements are protruded from the power element portion 510 formation regions. For these lead-out electrodes 512 protruded form the power element portions 510 as well, bumps 550 are placed directly above the lead-out electrodes.

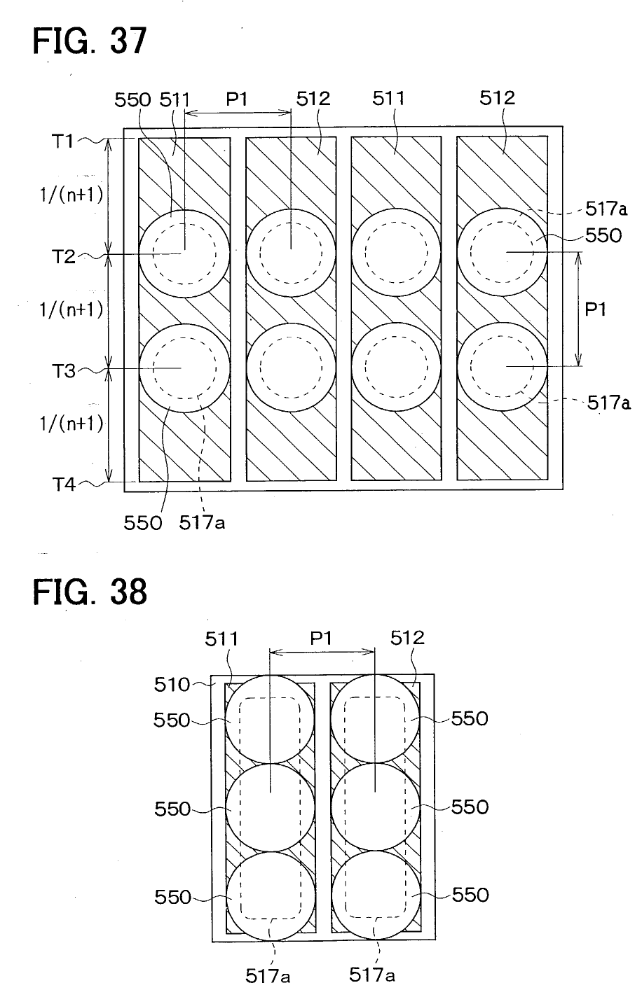

FIG. 37 is a schematic plan view of a second modification to this embodiment, taking a power element portion 510 as an example. This example relates to a case where one lead-out electrode is rectangular in a direction along the arrangement pitch P1 of bumps 550 and a plurality of the bumps 550 can be formed for the one lead-out electrode in a direction of the length thereof.

In the example illustrated in FIG. 37, lead-out electrodes 511 and 512 are rectangular in a direction of the arrangement pitch PI in a vertical direction in FIG. 37. Two bumps 550 are arranged for each lead-out electrode 511 and 512 with the arrangement pitch PI in the direction of the length of the electrodes.

At this time, with respect to each lead-out electrode 511 and 512, the end T1 of the electrode on one side, the center T2 of a first bump 550, the center T3 of a second bump 550, and the end T4 of the electrode on the other side are lined at equal intervals in the direction of the length of the electrode. That is, the distance between adjacent ones of these parts T1 to T4 is uniformly equal to one thirds of the length of the lead-out electrodes 511 and 512.

Here, consideration will be given to a case where, in this second modification, n bumps 550 are arranged for one lead-out electrode 511 and 512 in the direction of the length of the electrode. In this case, the distance between adjacent ones of the end of the electrode on one side, the center of the individual bumps 550, and the end of the electrode on the other side is equal to one (n+1)th of the length of the lead-out electrode 511 and 512, as illustrated in FIG. 37.

It is preferable that the shape of lead-out electrodes should be designed according to the arrangement pitch P1, as described with respect to the second modification. This is because, where a plurality of bumps 550 are formed for one lead-out electrode in the direction of the length of the electrode, the wiring resistance between the bumps 550 is uniformized.

FIG. 38 is a schematic plan view illustrating a third modification to this embodiment, taking a power element portion 510 as an example. Like the above second modification, this modification also relates to a case where a plurality of bumps 550 are formed for one lead-out electrode in the direction of the length of the electrode. However, this modification further relates to a case where a plurality of the bumps 550 on one lead-out electrode can be brought to the same potential.

In this case, the bumps 550 on one lead-out electrode 511 and 512 may be placed in contact with one another to provide continuity between the bumps, as illustrated in the FIG. 38. Continuity between the bumps 550 in contact and the lead-out electrode 511 and 512 is provided through common openings 517a formed in an insulating film 517.

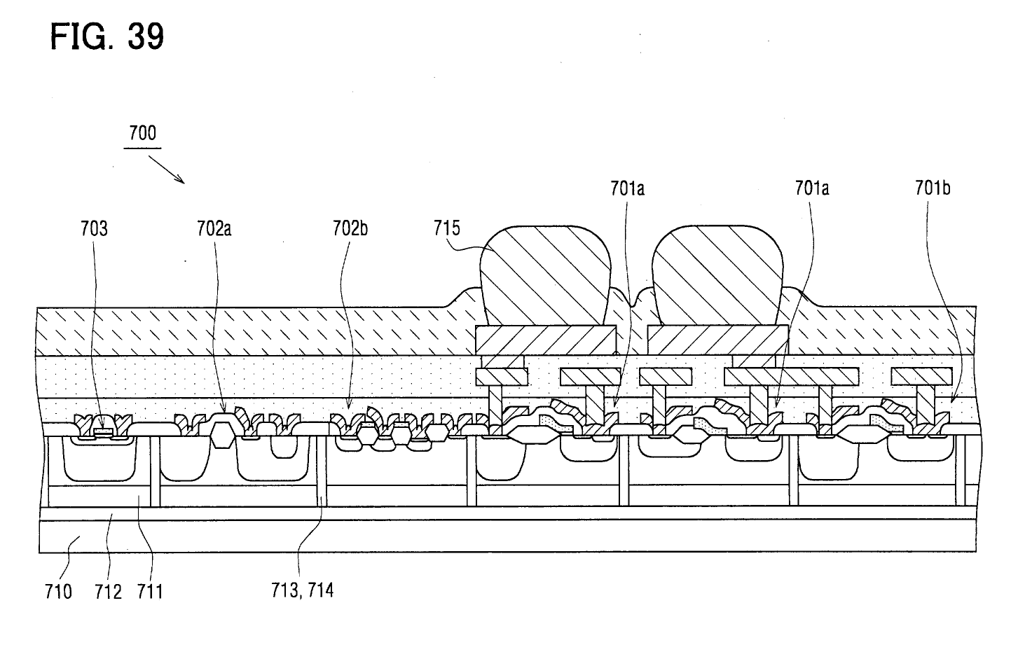

FIG. 39 is a schematic sectional view of a multiple-unit IC package of a forth modification. The multiple-unit IC package is a package where LDMOSs 701 (N 701a, P 701b) of a power element, bipolars 702 (NPN 702a, L-PNP 702b ), CMOSs 703 are formed on a chip 700 by using SOI (silicon on insulator) structure. Namely, firstly, a supporting substrate 710 and an n−substrate 711 constitute a laminated substrate with sandwiching a filled-in oxide film (SiO₂) therebetween. Secondly, an insulation trench 713 is formed, and an oxide film 714 is formed inside the trench 713. In a plurality of element regions that are isolated and insulated with each other, the above LDMOSs 701 and the others are formed.

Furthermore, as a feature of this modification, the LDMOSs 701 and the others are disposed right under bumps 715 or adjoin regions that are located right under the bumps 715. As a result, wiring pattern layers for leading out are thereby unnecessary. This structure exhibits an effect of lessening heating generation relating to the LDMOSs 701 of the power elements.

What is claimed is:

1. A semiconductor device comprising:
a connecting member that has certain electric potential and includes at least one connecting pad provided on a semiconductor substrate;
a plurality of bump electrodes provided for the connecting member; and
wiring for connecting the connecting member with the bump electrodes.

2. A semiconductor device according to claim 1,
wherein the wiring includes areal wiring that is extended substantially parallelly with a surface of the semiconductor substrate, and
wherein, in an overhead view relative to the surface of the semiconductor substrate, the areal wiring encircles the connecting member and the bump electrodes.

3. A semiconductor device according to claim 2,
wherein the areal wiring is comb-shaped and has a protrusion portion and a reception portion, and
wherein the areal wiring opposes adjacent areal wiring without short-circuiting between them, and the protrusion portion of one of the areal wiring and the adjacent areal wiring enters the reception portion of the other areal wiring.

4. A semiconductor device according to claim 2, wherein the areal wiring is provided with a slit.

5. The semiconductor device according to claim 4,
wherein the slit is provided at least in the areal wiring that is positioned at a peripheral portion of the semiconductor substrate.

6. A semiconductor device according to claim 4,
wherein a corner of the slit is cut off by at least one of chamfering and rounding.

7. A semiconductor device according to claim 2,
wherein a corner of the areal wiring is cut off by at least one of chamfering and rounding.

8. A semiconductor device according to claim 2,
wherein a protective film is formed on the surface of the areal wiring.
